(19) United States
(12) Patent Application Publication
(10) Pub. No.: US 2025/0072128 A1
(43) Pub. Date: Feb. 27, 2025

(54) GROUP III-V NANOWIRE-BASED AVALANCHE PHOTODIODE

(71) Applicant: North Carolina A&T State University, Greensboro, NC (US)

(72) Inventors: Shanthi Iyer, Greensboro, NC (US); Shisir Devkota, Hillsboro, OR (US); Mehul Parakh, Fremont, CA (US); Rabin Pokharel, Aloha, OR (US); Priyanka Ramaswamy, Boise, ID (US); Kendall Dawkins, Greensboro, NC (US); Jia Li, Greensboro, NC (US)

(73) Assignee: North Carolina A&T State University, Greensboro, NC (US)

(21) Appl. No.: 18/812,362

(22) Filed: Aug. 22, 2024

Related U.S. Application Data
(60) Provisional application No. 63/578,611, filed on Aug. 24, 2023.

(51) Int. Cl. H01L 31/107; H01L 31/0216; H01L 31/0304; H01L 31/0352

(52) U.S. Cl. CPC H01L 31/1075; H01L 31/02161; H01L 31/03046; H01L 31/035227

(57) ABSTRACT

The presently-disclosed subject matter relates generally to GaAs/GaAsSb core-shell nanowire grown on silicon substrate, methods of growing such nanowire, and the use of said nanowires in various applications, including but not limited to photodetection applications.

### CROSS-REFERENCE TO RELATED APPLICATION

This application claims the benefit of U.S. Provisional Application No. 63/578,611, filed Aug. 24, 2023, the entirety of which is incorporated herein by reference.

### STATEMENT AS TO RIGHTS TO INVENTIONS MADE UNDER FEDERALLY SPONSORED RESEARCH OR DEVELOPMENT

This invention was made with Government support under 1832117 awarded by the National Science Foundation and W911NF1910002 awarded by the Air Force Office of Scientific Research. The Government has certain rights in this invention.

### TECHNICAL FIELD

The presently-disclosed subject matter relates to Group III-V nanowires and their uses, including but not limited to photodetection applications.

### BACKGROUND

Infrared detection and imaging technology have seen significant growth in recent decades, with applications in optical interconnects, LiDAR, autonomous vehicle tracking, atmospheric sensing, communications, quantum computing, medicine, and astronomy. Avalanche photodetectors (APDs) and p-i-n heterostructures are leading developments in this field. Group III-V compound semiconductor nanowires can grow high-quality epitaxial layers with low residual carrier concentrations, resulting in devices with low leakage currents and capacitance, significantly enhancing quantum efficiency and supporting high-speed operation. These nanowires allow for the combination of homojunctions, heterojunctions, axial, and radial architectures, facilitating high-performance photodetector devices across various substrates.

Axial and core-shell nanowires generally exhibit good crystalline quality due to factors such as the vapor-liquid-solid (VLS) growth mechanism, tolerance to doping variations, and reduced interface defects from elastic strain relaxation. However, growing heterostructure nanowires with abrupt interfaces can pose challenges due to unintended radial growth and reservoir effects arising from solubility differences in catalyst droplets. This reservoir effect can be mitigated in Group III-V-V heterostructure nanowires by taking advantage of the lower solubility of group V species.

Among ternary III-V-V compound systems, GaAsSb stands out for photodetector applications due to its phase purity, high carrier mobility, and the ability to engineer the bandgap by varying Sb composition. GaAsSb's bandgap falls within the low-loss near-infrared telecommunication range, making it suitable for LIDAR and optical interconnections in supercomputers.

Research in semiconductor nanowires (NWs) has surged in the past decade. Group III-V semiconductor APDs have improved gain and sensitivity by reducing the impact ionization region in submicron heterostructures. Additionally, incorporating quantum heterostructures and nanophotonic resonances allows for greater design flexibility. Ensemble Group III-V nanowire APDs grown on silicon offer advantages such as strain relaxation and compatibility with silicon technology, enabling monolithic integration that enhances communication bandwidth and reduces costs. The small footprint and one-dimensional geometry of NWs provide versatility for various architectures and bandgap engineering, particularly when compared to thin-film photodetectors. Nanowires can achieve lower breakdown voltages, reduced dark count rates (DCR), and minimized jitter times, facilitating higher photon counting rates at room temperature.

With rising demand for low-light-level signal detection in the near-infrared (NIR) range, APDs are increasingly vital for commercial, military, and research applications, including optical communication, single-photon detection, deep space communication, surveillance, astronomy, autonomous vehicle tracking, and quantum cryptography. While planar Group III-V APDs show promise in the NIR range, they face challenges including incompatibility with CMOS technology due to lattice mismatch with silicon substrates, high-voltage operation, scaling difficulties, low external quantum efficiency, and reliance on external quenching circuits. In contrast, nanowires provide unique attributes, including enhanced optical trapping, strong nanophotonic resonances, reduced phonon scattering, and better accommodation of lattice mismatch. In the APD configuration, NWs offer advantages such as lower breakdown voltage, reduced excess noise, improved gain, faster response times, and increased light absorption compared to planar designs. Axially configured NWs can achieve APDs with enhanced gain, low photon flux sensitivity, and rapid response times, ultimately enabling higher photon counting rates.

Among ternary III-V-based semiconductor NWs, GaAsSb and InGaAs emit at telecommunications wavelengths of 1300 nm and 1550 nm, demonstrating excellent capabilities for infrared photodetector applications due to their tunable narrow bandgap in the near-IR range. GaAsSb specifically offers superior carrier mobility, longer electron lifetime, reduced Auger recombination, and a more stable electronic structure due to the presence of a single group-III element. In NW configurations, GaAsSb benefits from superior crystal quality owing to the surfactant nature of Sb, as well as opportunities for bandgap tuning.

### SUMMARY

In one aspect, the disclosed technology relates to an avalanche photodiode comprising: at least one GaAs/GaAsSb core-shell nanowire grown on a silicon substrate, wherein the GaAs/GaAsSb core-shell nanowire comprises: a nanowire core comprising an n-type GaAs; and a first shell enclosing the core; a second shell enclosing the first shell, wherein the first shell comprises an intrinsic type GaAs and is a multiplication region of the avalanche photodiode, wherein the second shell comprises a p-type GaAs and is a charge control region of the avalanche photodiode, and wherein the photodiode operates in a near-infrared region. In some embodiments, the avalanche photodiode further comprises a third shell enclosing the second shell, wherein the third shell comprises a p⁻-type GaAsSb and is an absorption region of the avalanche photodiode. In some embodiments, the avalanche photodiode further comprises a fourth shell enclosing the third shell, wherein the fourth shell comprises a p+-type GaAsSb and is a contact region of the avalanche photodiode.

In some embodiments, the avalanche photodiode further comprises a passivation layer enclosing the shell, wherein the passivation layer comprises Al, Ga, As, or a combination thereof. In some embodiments, diameter of the nanowire core is from about 30 nm to about 50 nm. In some embodiments, the radial thickness of the first shell is from about 30 nm to about 40 nm. In some embodiments, radial thickness of the second shell is from about 10 nm to about nm. In some embodiments, the radial thickness of the third shell is from about nm to about 30 nm. In some embodiments, the radial thickness of the fourth shell from about 20 nm to about 30 nm.

In some embodiments, the avalanche photodiode the first shell, the second shell, the third shell, and the fourth shell independently comprise from about 6 at. % to about 12 at. % of Sb. In some embodiments, the avalanche photodiode the third shell and the fourth shell independently comprise a band gap from about 0.95 eV to about 1.25 eV.

In another aspect, the disclosed technology relates to an avalanche photodiode comprising: at least one GaAs/GaAsSb axial nanowire grown on a silicon substrate comprising: a nanowire core comprising a bottom n-type GaAs stem region, a middle intrinsic-GaAs region, and an upper p-GaAs region; and a passivation layer enclosing the nanowire core comprising Al, Ga, As, or a combination thereof.

In some embodiments, the nanowire core further comprises an intrinsic-GaAsSb region on top of the p-GaAs region, and a p-GaAsSb region on top of the intrinsic-GaAsSb region. In some embodiments, the intrinsic-GaAsSb region comprises an Sb content from about 6 at. % to about 10 at. % Sb. In some embodiments, the p-GaAsSb region comprises an Sb content from about 2 at. % to about 6 at. % Sb, wherein the Sb content of the p-GaAsSb region is lower than an Sb content of the intrinsic —GaAsSb region.

Yet in another aspect, the disclosed technology further relates to an avalanche photodiode comprising: at least one hybrid axial/core-shell nanowire grown on a silicon substrate, wherein the hybrid axial/core-shell nanowire core-shell nanowire comprises: a nanowire core comprising a bottom n-type GaAsSb stem region, a middle intrinsic-GaAsSb region, and an upper p-GaAsSb region; and a shell enclosing the nanowire core comprising intrinsic-GaAsSb, wherein the shell is optionally doped with a Te-dopant.

In some embodiments, the shell enclosing the nanowire core is a first shell, and the hybrid axial/core-shell nanowire further comprises a second shell enclosing the first shell, wherein the second shell comprises p-GaAsSb and is optionally doped with a Be-dopant. In some embodiments, the middle intrinsic-GaAsSb region and the shell independently comprise an Sb content from about 2 at. % to about 12 at. %. In some embodiments, the avalanche photodiode further comprises a passivation layer enclosing the shell, wherein the passivation layer comprises Al, Ga, As, or a combination thereof. In some embodiments, the shell comprises i-GaAs_{0.74}Sb_{0.26}.

### BRIEF DESCRIPTION OF THE DRAWINGS

FIG. 1 illustrates a core-shell NW of the present disclosure.

FIG. 2 illustrates a hybrid core-shell NW of the present disclosure.

FIG. 3 shows SEM image of ensemble NWs grown on a silicon substrate.

FIGS. 4A and 4B show a NW diameter distribution (FIG. 4A) and NW length distribution (FIG. 4B).

FIGS. 5A and 5B illustrate a charge control, and multiplication region (SACM) avalanche photodiode (APD) (FIG. 5A) and band diagram (FIG. 5B) of the corresponding APD.

FIGS. 6A-6E depict capacitance measurement (FIG. 6A), Current-voltage (I-V) sweeps (FIG. 6B), dark current measurement (FIG. 6C), power dependence (FIG. 6D), and spectral response (FIG. 6E) of a device according to the present disclosure.

FIGS. 7A-7E depict capacitance measurements (FIGS. 7A and 7B) and noise measurements (FIGS. 7C-7E) of a device according to the present disclosure.

FIGS. 8A-8F depict dark I-V measurements (FIG. 8A), light I-V measurements (FIG. 8B), temperature dependent current measurements (FIG. 8C), Gain measurements (FIGS. 8D and 8E), and capacitance measurement (FIG. 8F) of a device according to the present disclosure.

FIGS. 9A-9F depict temperature dependent I-V measurement (FIG. 9A), inset enlarged breakdown region of FIG. 9A (FIG. 9B), breakdown voltage distribution of dark I-V measurements (FIG. 9C), Voltage-dependent dark and illumination I-V measurements (FIG. 9D), gain measurements (FIG. 9E), and capacitance-voltage measurements (FIG. 9F) of a device according to the present disclosure.

FIGS. 10A and 10B illustrate low-frequency noise measurements of the APD for different reverse bias voltage at 300 K (FIG. 10A) and 150 K (FIG. 10B).

FIG. 11 illustrates a schematic of single SACM axial NW APD.

FIGS. 12A-12C depict 4K photoluminescent (PL) spectroscopy (FIG. 12A), dark current variation with the reverse bias voltage (FIG. 12B), and Low Frequency Noise (LFN) spectroscopy at −1 V bias of the compensated and uncompensated intrinsic-segment (FIG. 12C).

FIGS. 13A-13C depict dark current (FIG. 13A), rectification ratio (FIG. 13B), and (I_{P}/I_{D}) ratio with intrinsic segment length in axial p-i-n NWs (FIG. 13C).

FIGS. 14A-14C depict dark current (FIG. 14A), photocurrent (FIG. 14B), and noise level (FIG. 14C) with different radial overgrowth suppression approaches of various devices of present disclosure.

FIGS. 15A-15C depict SEM images of GaAsSb axial p-i-n NWs: interruption for 1 min (FIG. 15A), without interruption (FIG. 15B), and interruption for 2 mins (FIG. 15C).

FIGS. 16A-16D depict superimposed characteristics of interrupted and uninterrupted NW samples: at room temperature (RT) PL (FIG. 16A), 4K PL (FIG. 16B), RT dark I-V (FIG. 16C), and LFN spectra (FIG. 16D).

FIG. 17 depicts SEM image of GaAsSb p-i-n heterostructure axial NWs.

FIGS. 18A-18B depict RT PL spectra (FIG. 18A), and 4K PL spectra (FIG. 18B) of NW of FIG. 17.

FIGS. 19A-19D depict superimposed dark and photocurrent (FIG. 19A), spectral response (−3 V) (FIG. 19B), C—V measurements at different frequencies (FIG. 19C), and LFN spectroscopy (−3 V) of the ensemble axial heterostructure p-i-n NW photodetectors (FIG. 19D) of present disclosure.

### DETAILED DESCRIPTION

The presently disclosed subject matter will now be described more fully. However, the presently disclosed subject matter can be embodied in different forms and should not be construed as limited to the embodiments set forth herein below and in the accompanying Examples. Rather, these embodiments are provided so that this disclosure will be thorough and complete, and will fully convey the scope of the embodiments to those skilled in the art.

All references listed herein, including but not limited to all patents, patent applications and publications thereof, and scientific journal articles, are incorporated herein by reference in their entireties to the extent that they supplement, explain, provide a background for, or teach methodology, techniques, and/or compositions employed herein.

While the following terms are believed to be well understood by one of ordinary skill in the art, the following definitions are set forth to facilitate explanation of the presently disclosed subject matter.

Unless defined otherwise, all technical and scientific terms used herein have the same meaning as commonly understood to one of ordinary skill in the art to which the presently disclosed subject matter belongs.

Following long-standing patent law convention, the terms “a” and “an” refer to “one or more” when used in this application, including the claims.

The term “and/or” when used in describing two or more items or conditions, refers to situations where all named items or conditions are present or applicable, or to situations wherein only one (or less than all) of the items or conditions is present or applicable.

The use of the term “or” in the claims is used to mean “and/or” unless explicitly indicated to refer to alternatives only or the alternatives are mutually exclusive, although the disclosure supports a definition that refers to only alternatives and “and/or.”

As used herein “another” can mean at least a second or more.

As used herein, the term “about”, when referring to a value is meant to encompass variations of in one example ±20% or ±10%, in another example ±5%, in another example ±1%, and in still another example ±0.1% from the specified amount, as such variations are appropriate to practice the disclosed documents.

In addition, all ranges disclosed herein are to be understood to encompass any and all subranges subsumed therein. For example, a stated range of “1.0 to 10.0” should be considered to include any and all subranges beginning with a minimum value of 1.0 or more and ending with a maximum value of 10.0 or less, e.g., 1.0 to 5.3, or 4.7 to 10.0, or 3.6 to 7.9.

All ranges disclosed herein are also to be considered to include the end points of the range, unless expressly stated otherwise. For example, a range of “between 5 and 10”, “from 5 to 10” or “5-10” should generally be considered to include the end points 5 and 10.

Further, when the phrase “up to” is used in connection with an amount or quantity, it is to be understood that the amount is at least a detectable amount or quantity. For example, a material present in an amount “up to” a specified amount can be present from a detectable amount and up to and including the specified amount.

As used herein, “nanowire” refers to an anisotropic wire-like structure. Nanowires, including the structures disclosed in this document, are essentially one-dimensional with nanometer dimension in width or diameter of about 1 to about 1000 nm, including for example about 1 to about 600 nm, about 1 to about 500 nm, about 1 to about 400 nm, about 1 to about 300 nm, or about 1 to about 300 nm. The lengths of nanowires are typically in the range of about a few 100 nm to up to about 10 μm. Nanowires can have an aspect ratio of at least about 2, at least about 5, at least about 10, at least about 50, at least about 100, at least about 250, or at least about 500. It is further to be understood that a nanowire described herein can be cylindrical or substantially cylindrical. A nanowire described herein can also be faceted, as opposed to having a continuously curved circumference. Nanowires can be designated as axial, as core-shell or as axial/core-shell hybrid, based on the stacking of different semiconductor layers or segments along the length of the nanowire axis (vertically) or radially or a combination thereof; such a designation does not refer nor is governed by the presence of a passivation shell found on the nanowires of the present application.

In some embodiments, the nanowires disclosed herein are coated with a passivation layer, which passivates the surface states of the nanowire, generally wherein the passivation layer includes a material having a higher band gap compared to the NW. In some embodiments, the passivating layer includes GaAs or AlGaAs; in some embodiments the passivating layer includes GaAs and AlGaAs. The GaAs- and/or AlGaAs-containing layer is typically grown by a vapor-solid technique.

The passivation layer generally surrounds (or covers or “overcoats”) or substantially surrounds (or covers or “overcoats”) the nanowires. As understood by one of ordinary skill in the art, a passivation layer that “surrounds” or “substantially surrounds” (or “covers” or “substantially covers” or “overcoats” or “substantially overcoats”) the nanowire can surround or substantially surround (or cover or substantially cover or overcoat or substantially overcoat) the circumference of the nanowire, such that the layer surrounds or substantially surrounds (or covers or overcoats) the nanowire radially. The layer may also surround or substantially surround (or cover or substantially cover or overcoat or substantially overcoat) the nanowire on the ends or faces of the nanowire longitudinally (i.e., at the “tip” or at the ends of the “length” or “long dimension” of the nanowire). Additionally, the passivation layer can surround (or cover or overcoat) at least about 75%, at least about 80%, at least about 85%, at least about 90%, at least about 95%, at least about 98%, or at least about 99% of the relevant surface or surfaces of the nanowire, based on area. Thus, in some cases, the passivation layer completely or substantially completely surrounds, covers, or overcoats the nanowire.

It is further to be understood that nanowires disclosed herein can have any total dimensions not inconsistent with the objectives of the present disclosure. For example, in some cases, the nanowires can have an average diameter of no more than about 500 nm, no more than about 400 nm, or no more than about 300 nm. In some embodiments, the nanowires have an average diameter of between about 100 to about 500 nm, about 100 to about 400 nm, about 100 to about 300 nm, about 100 to about 200 nm, about 100 to about 250 nm, about 150 to about 300 nm, or about 150 to about 250 nm. Further, in some embodiments, the nanowires have an average length of at least about 500 nm, at least about 1 μm, at least about 2 μm, at least about 3 μm, at least about 4 μm, at least about 5 μm, at least about 10 μm, at least about 15 μm, at least about 20 μm, at least about 25 μm, at least about 30 μm, at least about 40 μm, or at least about 50 μm. In some instances, the nanowires have an average length of about 500 nm to about 1 μm, about 500 nm to about 2 μm, about 500 nm to about 5 μm, about 500 nm to about 10 μm, about 750 nm to about 1 μm, about 750 nm to about 2 μm, about 750 nm to about 5 μm, about 750 nm to about 10 μm, about 1 to about 5 μm, about 1 to about 10 μm, about 1 to about 20 μm, about 2 to about 5 μm, to 2 about 10 μm, about 2 to about 20 μm, or about 5 to about 20 μm. Additionally, such nanowires can also have an aspect ratio of at least about 20, at least about 50, or at least about 100. In some cases, core-shell nanowires have an aspect ratio of about 1 to about 50, about 1 to about 30, about 1 to about 20, about 5 to about 50, about 5 to about 30, about 5 to about 20, about 10 to about 50, about 10 to about 30, or about 10 to about 20.

Each of the core-shell nanowires described herein comprise a core. As understood by one of ordinary skill in the art, a “core” of a core-shell nanowire can itself be a nanowire, where a “nanowire” is understood to refer to an anisotropic material or particle having a diameter (d) or size in two dimensions (e.g., height and width) of about 1 to about 1000 nm, about 1 to about 500 nm, or about 1 to about 100 nm, and an aspect ratio of at least about 10, at least about 50, or at least about 100. A nanowire described herein can be cylindrical or substantially cylindrical.

The core of a core-shell nanowire described herein can have any size and shape not inconsistent with the objectives of the present disclosure. In some embodiments, the core has an average diameter of no more than about 150 nm, no more than about 120 nm, no more than about 100 nm, no more than about 80 nm, no more than about 60 nm or no more than about 40 nm. In some embodiments, the core has an average diameter of about 50 to about 110 nm or about 70 to about 90 nm.

Core-shell nanowires described herein also comprise a shell, optionally a first shell, a second shell, a third shell or an overcoat shell surrounding (or covering or “overcoating”) or substantially surrounding (or covering or “overcoating”) the core, the first shell, the second shell, etc of the nanowires. As understood by one of ordinary skill in the art, a shell that “surrounds” or “substantially surrounds” (or “covers” or “substantially covers” or “overcoats” or “substantially overcoats”) the core or an earlier applied shell can surround or substantially surround (or cover or substantially cover or overcoat or substantially overcoat) the circumference of the core or earlier applied shell, such that the first or second shell surrounds or substantially surrounds (or covers or overcoats) the core or earlier applied shell radially. The shell may also surround or substantially surround (or cover or substantially cover or overcoat or substantially overcoat) the core or earlier applied shell on the ends or faces longitudinally (i.e., at the ends of the “length” or “long dimension” of the core or earlier applied shell). Additionally, the first shell can surround (or cover or overcoat) at least about 80%, at least about 85%, at least about 90%, at least about 95%, at least about 98%, or at least about 99% of the relevant surface or surfaces of the core or earlier applied shell, based on area. Thus, in some cases, the shell completely or substantially completely surrounds, covers, or overcoats the core or earlier applied shell. In some embodiments, the second shell has an average thickness of at least about 5 nm or at least about 10 nm. In some cases, the second shell has an average thickness of about 10 to about 30 nm. Other thicknesses are also possible.

It is to be understood that the value of x (i.e., the antimony content) as disclosed herein in axial or core-shell configurations can be determined according to scanning transmission electron microscope (STEM) energy-dispersive x-ray spectroscopy (EDS) analysis, consistent with methods disclosed in the art.

As used herein “axial nanowire” refers to a nanowire containing the active components in an axial configuration (e.g., axially stacked along the nanowire length). In an axial configuration, the ‘stem region’ is generally the ‘bottom’ of the nanowire, i.e., the area of the nanowire that is adjacent to the substrate; the ‘upper region’ is generally that area of the nanowire that is not adjacent to the substrate and is at the ‘top’ of the nanowire, relative to the substrate being the ‘bottom.’

While nanowires grown on unpatterned substrates are exemplified herein, growth on patterned substrates can also be achieved according to the methods disclosed herein. The growth of nanowires on a patterned substrate as described herein included pre-patterning of the substrate. As is known to those of skill in the art, electron beam lithography (EBL) is one method that can be used for pre-patterning, and process parameters such as beam current, dose time, reactive ion etching (RIE) duration can be selected to provide desired growth conditions for the targeted axial, core-shell or axial/core-shell hybrid nanowire. Generally, the nanowires disclosed herein are grown on an unpatterned silicon substrate, such as n-Si<111>, but the disclosed methods can also apply to other substrates, including for example, GaAs. The methods of nanowire growth can also be used to grow nanowires of the present application on a patterned silicon substrate, such as patterned Si, which can be prepared using methods known to those of skill in the art, including for example, Electron Beam Lithography, which makes a nanoscale array of holes in an oxide layer of a silicon substrate for the growth of patterned array of nanowires.

In some embodiments, the structural components of the axial or core-shell or axial/core-shell hybrid nanowires are undoped; such undoped regions can be described as intrinsic, and may have p-type or n-type electronics. Such undoped regions of GaAs layers can be described as intrinsic. In the case of GaAsSb, undoped layers are slightly p-type and can be compensated by small amounts of n-type dopant. In some embodiments, the structural components of the axial and/or core-shell nanowires disclosed herein are doped. The regions that are prepared with a dopant include GaAs, GaAsSb and GaAs₁₋ₓSbₓ regions. As disclosed herein, in some embodiments, nanowires comprise GaAsSb, typically such structural components have a uniform Sb content, such as, for example, between about 5 atomic % (at %) and about 12 at %, or between about 7-10 at % or about 5 at %, 6 at %, 7 at %, 8 at %, 9 at %, 10 at %, 11 at %, or 12 at %. In some embodiments, the dopant is, for example, a beryllium (Be), tellurium (Te), tin (Sn), silicon (Si), selenium (Se), or sulfur (S) dopant; in some embodiments, the dopant is Te. In some embodiments, the dopant is Be. The type of dopant is informed by the electronic properties needed in the particular axial or core shell component, particularly in view of the adjacent axial region or core/shell. In some embodiments, Te is an n-type dopant. In some embodiments, Be is a p-type dopant.

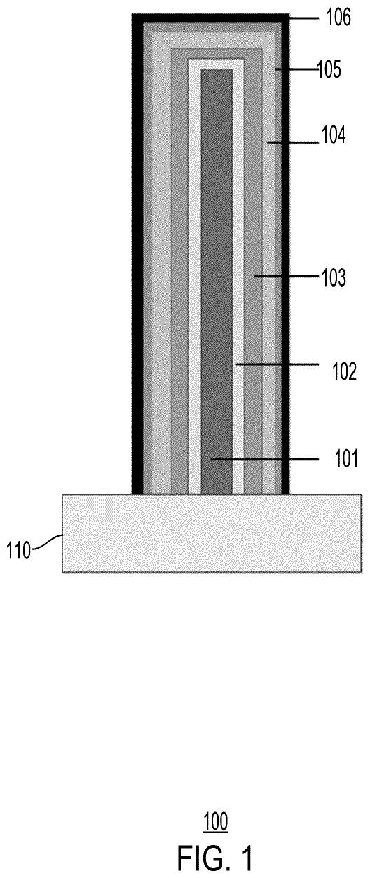

In one aspect, the present application discloses a GaAs/GaAsSb core-shell configured nanowire-based avalanche photodiode having up to 1.3 μm light detection. As seen in FIG. 1, disclosed herein is a GaAs/GaAsSb core-shell configured nanowire (NW) based separate absorption, charge control, and multiplication region (SACM) avalanche photodiode (APD) operating in the near-infrared (NIR) region, i.e., 800-2500 nm. Heterostructure NWs consisted of GaAs and tunable bandgap GaAs₁₋ₓSbₓ serving as the multiplication and absorption layers, respectively. GaAs/GaAsSb core-shell configuration nanowire grown on Si type substrate 110 comprises n-type GaAs core 101, intrinsic GaAs shell layer 102 (i.e., a first shell), p⁻-type GaAs shell layer 103 (i.e., a second shell), an n-type GaAsSb layer 104 (i.e., a third shell), a P+(i.e., heavy p-type doping) type GaAsSb layer 105 (i.e., a fourth shell), and AlGaAs/GaAs passivation layer 106. In some embodiments, intrinsic GaAs shell layer 102 is a multiplication region of avalanche photodiode, p⁻-type GaAs shell layer 103 is a charge control region of avalanche photodiode, n-type GaAsSb layer 104 is an absorption region of avalanche photodiode, and P+(i.e., heavy p-type doping) type GaAsSb layer 105 is a contact region of avalanche photodiode.

A doping compensation of absorber material to boost material absorption, segment-wise annealing to suppress trap-assisted tunneling, and an intrinsic i-type and n-type combination of the hybrid axial core to suppress axial electric field led to the preparation of a room temperature avalanche photodetection extending up to about 1.3 μm. APD device operating at room temperature with a unity-gain responsivity of about 0.2 to about 0.25 A/W at ˜5 V, the peak gain of about 160 at 1064 nm and 18V reverse bias, gain>50 at 1.3 μm are further disclosed herein.

As disclosed herein, a self-catalyzed, epitaxially grown GaAs/GaAsSb core-shell (CS)-based nanowire SACM APD is prepared and incorporated into near-infrared photodetection. GaAs and GaAsSb material systems in NW configuration have the advantage of having a single group III element especially compared to those with multiple Group III material systems, which may lead to inhomogeneous composition. The CS-configured NWs of the present application show increased device sensitivity, attributed to the decoupling of vertical light absorption and radial carrier generation. Conveniently, the control of growth parameters disclosed herein for shell layers is less stringent than several axial counterparts. The disclosed GaAs/GaAsSb-based CS NW heterostructure design exemplified herein achieve room temperature photodetection up to 1.3 μm using tunable bandgap GaAsSb absorber material, a wider-bandgap GaAs multiplication, and charge control regions. A narrow bandgap region for light absorption and a higher bandgap multiplication region was designed to enable low noise photodetection. The absorption band of GaAsSb covers the entire telecommunication bands up to the C band (1530-1565 nm), which is tuned by varying the Sb composition. The disclosed CS NW device uses a tunable bandgap GaAsSb as the absorber material. The composition of GaAs₁₋ₓSbₓ corresponds to the bandgap range of about 0.95 eV to about 1.25 eV, as determined from photoluminescence measurements. Temperature-dependent current-voltage (I-V), capacitance-voltage (C—V), low-frequency noise (LFN) measurements, and intensity dependence of photocurrent measurements provide insights into the material and interface traps and their effects on the nature of the breakdown mechanisms which suppressed the band-to-band tunneling responsible for Zener breakdown in the nanoscale-wide heterostructures via judicious 3D-heterostructure design to impact the ionization process with improved photodiode performance.

In some embodiments, the SACM core shell NW APDs show a VBR range from −25±2 V, with good gain in linear mode APD which is highly desired for low power APDs.

The APDs additionally show a Gain (M)>20 below VBR, and thereafter as high as ˜200 at breakdown. They also show a positive VBR coefficient of about +50 mV/K in the temperature range of 77 K to 200 K, with distinct sharp breakdown characteristics under dark, attesting to the presence of a band-to-band avalanche mechanism. A low device capacitance of about 1-2 pF was observed after complete depletion, which enables high-speed operation for such APD devices. The room temperature (RT) responsivity was about 0.2 A/W at 5 V and detectivity at −5 V was about 1×10¹⁰-5×10¹⁰ Jones.

As disclosed herein, the core-shell configured GaAs/GaAsSb based SAM nanowire APD showed RT operation; in particular, an avalanche gain exceeding 250 at RT was demonstrated with a very low device capacitance. A low dark current of nano-amperes was achieved at punch-through.

As disclosed herein, the material properties were the result of segment-wise in-situ growth structures annealing. Without being bound by theory, the compensated absorption layer maximized the light absorption in the NWs.

Disclosed herein is the room temperature operation of a highly sensitive avalanche photodetector which operates at wavelengths beyond 1 μm and overcomes many limitations of conventional Si detectors. Bandgap tuning can be controlled by varying the Sb composition in the absorption layer and does not have a considerable impact on the multiplication noise of the photodetector.

In one aspect, compositions comprising one or more core-shell nanowires are described herein. In some embodiments, a core-shell nanowire comprises a core and a first shell surrounding or substantially surrounding the core and a second shell surrounding or substantially surrounding the first shell. In some embodiments, the core is formed from GaAs, such as n-type (N+)—GaAs; the first shell is also formed from GaAs, such as i type (intrinsic, i) GaAs or Be (beryllium)-doped GaAs; the second shell is a GaAsSb absorption layer, and the third shell is a highly p-doped GaAsSb contact layer. Finally, a passivation layer, such as AlGaAs covers the nanowire. The composition of the GaAsSb layer varied from about 5 to about 30 atomic percentages (5-30 at %). Additionally, in some cases, the nanowires have an average emission maximum of about 1.25-1.35 μm, for example, up to about 1.3 μm, including at room temperature.

In some embodiments, the present application discloses a core-shell nanowire, wherein the core may comprise n-GaAs having a core diameter from about 30 to about 50 nm, about 30 to about 35 nm, about 35 to about 40 nm, about 40 to about 45 nm, or about 45 to about 50 nm, a first shell comprising i-GaAs (multiplication layer), having a radial thickness of about 25 to about 40 nm, about 25 to about 30 nm, about 30 to about 35 nm, about to about 40 nm, or about 30 to about 40 nm, a second shell comprising p-GaAs (a charge control layer) having a radial thickness of from about 10 nm to about 20 nm, i.e., 12±3 nm, third shell comprising P- (low p-type doping) GaAsSb, (an absorption layer) having a radial thickness of from about 20 nm to about 30 nm, i.e., 25±3 nm with an Sb incorporation of ˜10 at. % for example, from about 2 at. % to about 12 at. %, about 2 at. %, about 3 at. %, about 4 at. %, about 5 at. %, about 6 at. %, about 7 at. %, about 8 at. %, about 9 at. %, about 10 at. %, about 11 at. %, or about 12 at. %. In some embodiments, Sb content of each region may independently comprise about 2 at. % to about 12 at. %, about 2 at. %, about 3 at. %, about 4 at. %, about 5 at. %, about 6 at. %, about 7 at. %, about 8 at. %, about 9 at. %, about 10 at. %, about 11 at. %, or about 12 at. %. of Sb. In some embodiments, the core shell nanowire further comprises a fourth shell comprising P+ GaAsSb (a contact layer) having a radial thickness of from about 20 nm to about 30 nm, and a passivation layer comprising Al, Ga, As or a combination thereof, for instance, AlGaAs, GaAs, or AlGaAs/GaAs.

In one aspect, the present application discloses an ensemble GaAsSb/GaAs axial configured nanowire-based separate absorption, charge control, and multiplication avalanche near-infrared photodetector applications.

In particular, the present application discloses high-density as-grown ensemble GaAs₁₋ₓSbₓ/GaAs based Separate Absorption, Charge, and Multiplication (SACM) axial NW APD grown directly on a substrate, which can be patterned or non-patterned; such a substrate can be silicon.

The disclosed nanowire operates in a technologically relevant Near-IR regime, at or near wavelengths of 1.06 μm; and broad spectral wavelength response was observed out to 1.2 μm. The SACM based axial NW APDs show reduced dark current (little to no parasitic growth) and increased absorption, which, without being bound by theory, is attributed to the plasmonic antenna effect. As shown herein, C—V and temperature-dependent low-frequency noise measurements attest to the presence of an avalanche mechanism in the NW APDs to complement I-V characteristics results.

As shown herein, synthesis of the nanowires of the present application benefited from careful attention to growth techniques, including shutter sequencing, growth temperature, and V/III flux variation throughout NW growth to address issues like effective dopant incorporation, dopant diffusion, lateral overgrowth, and inverse tapering during axial NW growth.

In some embodiments, the ensemble SACM axial NW APDs show a low VBR range from −10±2 V, which is highly desired for low power APDs. They additionally show a gain (M)˜20 below VBR, and thereafter as high as ˜700. Additionally, they show a positive VBR coefficient˜+12.6 mV/K in the temperature range of 77 K to 300 K, which was noted with distinct sharp breakdown characteristics under dark, attesting to the presence of a band-to-band avalanche mechanism. The ensemble SACM axial NW APDs additionally demonstrate low device capacitance (˜0.67 pF) after complete depletion was observed.

As shown herein, molecular beam epitaxially grown axially configured ensemble GaAsSb/GaAs separate absorption, charge, and multiplication (SACM) region-based nanowire avalanche photodetector device on non-patterned Si substrate have been prepared and exhibit low breakdown voltage (VBR)˜−10±2.5 V under dark, photocurrent gain (M) varying from 20 in linear mode to avalanche gain of 700 at VBR at a 1.064 μm wavelength. Positive temperature dependence of breakdown voltage˜12.6 mV/K affirms avalanche breakdown as the gain mechanism in the disclosed SACM NW APDs. Capacitance-voltage (C—V) and temperature-dependent noise characteristics validated punch-through voltage ascertained from I-V measurements, consistent with avalanche as the dominant gain mechanism in the APDs. The ensemble SACM NW APD device demonstrated a broad spectral room temperature response with a cut-off wavelength of ˜1.2 μm with a responsivity of ˜0.17-0.38 A/W at −3 V.

The GaAsSb/GaAs system disclosed herein is a SACM APD in the axial NW geometry in the ensemble configuration grown on non-patterned Si substrates. The higher bandgap GaAs is used to reduce multiplication noise. GaAsSb has excellent absorption characteristics spanning almost the entire NIR region and offers ease in bandgap engineering due to the presence of two group V elements, and exhibits high structural phase purity in the NW configuration, particularly compared to InGaAs-containing NW. NW growth compatibility with a multiplication layer of GaAs makes it an excellent candidate as an absorption region material. The disclosed SACM-based structure allows for independent control of electric field intensity in different regions of a single axial NW APD structure, which in turn enables tuning the absorption region wavelength regime, and breakdown voltage and reduces dark current density, thus decoupling the effective device sensitivity and the target operational wavelength.

Electric field (E-field) simulations informed the device design disclosed herein. Variations in growth temperature during the segment-wise axial growth and shutter sequencing led to the successful demonstration of the avalanche mechanism in the axial NWAPD device. Temperature-dependent current-voltage (I-V) measurements provided insight into the nature of the breakdown voltage mechanism and led to growth conditions that yielded successful APD devices. Capacitance-voltage (C—V) and low-frequency noise measurements attested to avalanche characteristics in the NW device.

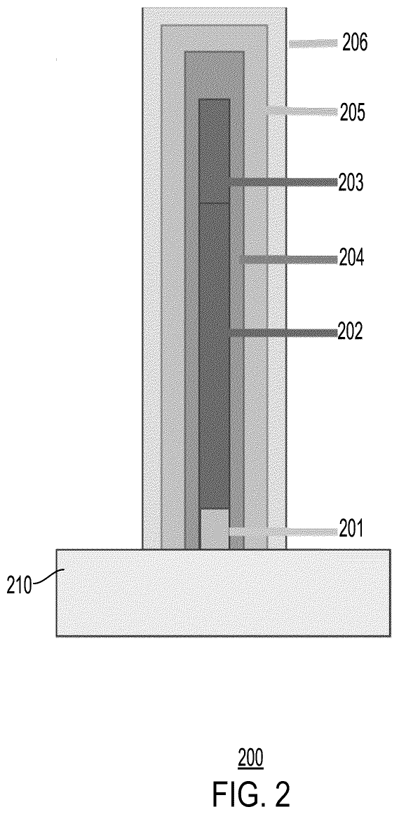

In another aspect, the present application discloses a MBE-grown GaAsSb NW-based core-shell n-i-p heterojunction photodetector. It should be understood that the components of the GaAsSb NW-based core-shell n-i-p heterojunction photodetector may comprise the same, similar, or substantially similar components, features, dimensions, chemical composition as GaAs/GaAsSb core-shell of FIG. 1. As shown in FIG. 2, GaAsSb NW-based core-shell n-i-p heterojunction photodetector may comprise GaAsSb NW comprising n-i-p heterojunction core configuration. In some embodiments, GaAsSb NW grown on Si type substrate 210 may comprise i-GaAs, n-GaAs, or i-GaAs/n-GaAs stem 201, n-type GaAsSb core 202, intrinsic GaAsSb GaAsSb core 203 forming n-i-p heterojunction. In some embodiments, NW may comprise intrinsic GaAsSb shell 204 enclosing the core, p-type GaAsSb shell 205 enclosing the shell 204, and/or AlGaAs/GaAs passivation layer 206 enclosing the shell 205.

In some embodiments, Sb content of each region described in FIG. 2 may independently comprise about 2 at. % to about 12 at. %, about 2 at. %, about 3 at. %, about 4 at. %, about 5 at. %, about 6 at. %, about 7 at. %, about 8 at. %, about 9 at. %, about 10 at. %, about 11 at. %, or about 12 at. %. of Sb.

In some embodiments, this nanowire representation explicitly includes an i-GaAs/n-GaAs stem. A stem, which can be i-GaAs/doped GaAs, is present in every axial and core shell nanowire structure disclosed herein and in all GaAs nanowires.

As disclosed herein, is a room temperature MBE-grown conventional Core-Shell n-i-p GaAsSb NW-based near infrared photodetector operating at wavelengths of up to about 1.1 μm with responsivity and detectivity of 190 A/W and 1.1×10¹⁴ Jones, respectively at −1 V.

The hybrid axial core/shell nanowire has 1500 nm activity and good responsivity and detectivity on an unpatterned substrate; a patterned substrate allows for control of density and reduced parasitic growth, leading to improved properties.

Shown herein is a method of vertical growth of Te-doped GaAsSb NWs on n-type Si substrate. In one embodiment, the optimized temperature for Te compensation was between about 520° C. and about 540° C., or about 530° C. The oxidation duration and growth temperature, using a 2-step temperature growth, was optimized for the vertical uniform growth of Te-doped GaAsSb NWs on an n-type Si substrate. In some embodiments, an oxidation duration of 90 mins and 120 mins with initial Ga opening for 9 sec at 615° C. and 8 mins of GaAs stem growth yielded vertical dense GaAsSb-containing NWs of the present application. In particular, growth of core Te-doped GaAs0.97Sb0.03 for the oxidation time of 90 mins with an initial Ga opening for 9 sec at 615° C. and 8 mins of GaAs stem followed by core Te-doped GaAs0.90Sb0.10 at 590° C., yielded a vertical dense Te-doped GaAs0.97Sb0.03 NWs for a V/III ratio of 10. Droplet consumption with the same As flux was at 550° C. for 8 mins.

Growth of intrinsic GaAs0.95Sb0.05 shell was seen at 550° C. with a wavelength emission of 1.1 μm. According to one embodiment, in situ vacuum annealing after the growth of the p-segment allowed for high Be incorporation. In another aspect, the present application discloses a room temperature-hybrid axial core-shell n-i-p GaAsSb nanowire-based near infrared photodetector operating at up to 1.5 μm, having a high responsivity and detectivity of about 18 A/W and 1.1×10¹³ Jones, respectively at −1 V.

In some embodiments, one or more of the following steps led to the fabrication of novel high-quality room temperature core shell (C-S) n-i-p GaAsSb NW-based PD: The conventional structure of the C-S n-i-p GaAsSb was redesigned and a small segment of i-GaAsSb was grown on the core Te-doped GaAsSb. Without being bound by theory, the change improved the light absorption volume for an enhanced device and reduced the possible impact of over-etching of the p- and i-shell during metal contact fabrication. The core intrinsic GaAsSb was grown on top of Te-doped GaAsSb core, yielding an increased the absorption length. Droplet consumption with the same As flux at 465° C. for 8 mins yielded a more uniform NW tip. In-situ vacuum annealing after the growth of each n-, i-, p-segment facilitated the formation of a uniform junction and improved Te and Be incorporation. Growing the nanowires at a higher ratio (e.g., flux ratio of ((As+Sb)/Ga=10 in n region, 11 in I region and 11 in p region)), avoided the beak-like nanowire growth which can be caused by a high Be cell temperature.

The methods disclosed herein enabled growth of an intrinsic GaAs_{0.74}Sb_{0.26} shell at 550° C. with a wavelength emission of 1.5 μm.

Disclosed herein are high-performance self-assisted molecular beam epitaxy (MBE) grown conventional core-shell n-i-p GaAsSb nanowires (NWs) and novel hybrid axial C-S n-i-p GaAsSb ensemble NWs based near-infrared photodetector (NIRPD) on non-patterned Si substrate. The conventional room temperature (RT) C-S n-i-p GaAsSb NW with a high responsivity of about 190 A/W and a higher detectivity of about 1.1×10¹⁴ Jones at −1V bias at the wavelength of about 1.1 μm was measured. In part resulting from modifying the intrinsic region thickness and appropriately compensating the intrinsic p-type behavior with n-dopant Te. A hybrid axial C-S n-i-p GaAsSb has been bandgap engineered for the wavelength up to 1.5 μm exhibiting a responsivity of about 18 A/W and detectivity of about 1.1×10¹³ Jones operating at RT. In this hybrid design, both axial and radial intrinsic (i-) segments of different Sb % compositions were combined to enhance the photoabsorption in the NIR region, hence the photogenerated current and the high bandgap axial i-region helps to suppress the trap-assisted tunnelling mechanism, an improvement over conventional C-S NW architectures. In addition, high rectification ratio from current-voltage measurements (I-V), suppression of low frequency noise, lack of 1/f noise, a low corner frequency of ˜2.5 Hz beyond which the presence of only frequency-independent white noise from low-frequency noise measurements (LFN), and bias- and frequency-dependent capacitance-voltage (C-V) measurements are consistent with the formation of a high-quality C-S junction in the hybrid structure. The hybrid axial C-S NW architecture of the present application provides the flexibility of 3D design and offers a path for expanding IRPD and other next-generation optoelectronic device applications.

The C-S n-i-p GaAsSb NW configuration suppresses the dark current and, compared to the axial configuration, exhibits improved device performance due in part to (a) decoupling of light absorption and carrier extraction, (b) high carrier collection efficiency, in part because the carriers' transit distance across the NW radially is small compared to the minority carrier diffusion length, which leads to low non-radiative recombination, and (c) a large junction area, providing a large volume for absorption. As shown herein, the C-S NW configuration provides more flexibility in device design necessary for RT NIRPD and extends the wavelength of operation by tuning the intrinsic region, which plays a key role in the absorption of light. An increase in intrinsic region thickness provides a large volume for absorbing more light, resulting in more photogenerated carriers, increased quantum efficiency, and transit time. In particular, the C-S NW structure disclosed herein successfully balances these two competing mechanisms (quantum efficiency and transit time) due to the large junction area and high carrier collection efficiency.

In one aspect, the present application discloses the growth of ensemble Group III-V p-i-n NWs and the incorporation of such nanowires in an ensemble photodetector. In some embodiments, the present application discloses a sequence of growth experiments and characterization of self-catalyzed molecular beam epitaxially grown GaAsSb heterostructure axial p-i-n nanowires (NWs) on p-Si<111>, which can be employed in ensemble photodetector (PD) applications in the near-infrared (NIR) region. As shown herein, successful growth approaches were identified as (a) Te-dopant compensation, to suppress the p-type nature of the intrinsic GaAsSb segment, (b) growth interruption, to resolve strain relaxation at the interface, (c) decreased substrate temperature, to enhance supersaturation and minimize the reservoir effect, (d) higher bandgap compositions of the n segment of the heterostructure relative to the intrinsic region, for boosting absorption, and (e) high-temperature ultra-high vacuum in-situ annealing, to reduce parasitic radial overgrowth. The resulting heterostructure p-i-n NWs had enhanced photoluminescence (PL) emission, suppressed dark current, in addition to increased rectification ratio, photosensitivity, and a reduced low-frequency noise level. The PD fabricated with the GaAsSb axial p-i-n NWs of the present application exhibited a longer wavelength cutoff at ˜1.1 μm with a significantly higher responsivity (about 120 A/W @-3 V bias) and detectivity (about 1.1×10¹³ Jones) at room temperature. Frequency and bias-independent capacitance in the pico-Farad (pF) range and a substantially lower noise level at the reverse-biased condition reinforce the use of p-i-n GaAsSb NWs PD for high-speed optoelectronic applications.

The improved performance NW device relies on a number of factors, including controlling the growth conditions to yield a high-quality heterostructure. Disclosed herein is a series of growth steps that mitigate several challenges from the self-assisted molecular beam epitaxial growth of GaAsSb NW heterostructure in axial geometry. The disclosed method steps suppress the effects of the Ga droplet reservoir effect and the radial overgrowth issues. The growth of an intrinsic GaAsSb segment with low background carrier concentration poses a challenge, stemming from this material system's intrinsic p-type nature caused by inherent Ga antisite defects; the challenge was alleviated by appropriately compensating with n-type Te doping. The high-quality heterostructure GaAsSb p-i-n axial NW segments of different Sb compositions prepared by the methods of the present application are attested by the presence of a room temperature photoluminescence (PL) signal and distinct two 4K PL peaks with a higher energy tail. High p-i-n NW photosensitivity has been achieved in part by variation of the substrate temperature and beam equivalent pressure (BEP) of flux during NW growth. An ensemble NW photodetector fabricated from the resulting NW exhibited bandpass characteristics with a longer wavelength cutoff at ˜1.1 μm with a responsivity of about 120 A/W and detectivity of about 1.3×10¹³ Jones.

In some embodiments, the present application provides the ability to integrate the disclosed nanowires-based photodetectors with current CMOS image sensor technology for higher sensitivity, higher resolution, and lower power consumption image sensors.

### EXAMPLES

The following Examples have been included to provide guidance to one of ordinary skill in the art for practicing representative embodiments of the presently disclosed subject matter. Considering the present disclosure and the general level of skill in the art, those of skill can appreciate that the following Examples are intended to be exemplary only and that numerous changes, modifications, and alterations can be employed without departing from the scope of the presently disclosed subject matter.

### Example 1

Samples were grown on an epi-ready n-type Si (111) substrate via the vapor-liquid-solid (VLS) mechanism by molecular beam epitaxy (MBE) using As₄ and Sb₂ species at a varying growth temperature from 550° C. to 615° C. The Ga cell temperature and arsenic (As) cracker cell temperature set for As₄ species were preset to a beam equivalent pressure (BEP) group V/III ratio of 10 to yield a nominal GaAs thin film growth rate of 0.25 monolayer/second (ML/s). A 10-second Ga pre-deposition was used for self-catalyzed growth. The GaAs core was grown at a temperature of 600° C. at a group V/III BEP ratio of about 10, followed by intrinsic and Be-doped GaAs segment growth at 550° C. at a group V/III BEP ratio of about 12. The substrate temperature was increased to 590° C. for the GaAsSb absorption layer and the growth of the highly p-doped GaAsSb contact layer. The composition of the GaAsSb layer varied from ˜5 to ˜30 atomic percentages (5-30 at. %). A low-doped passivation layer of AlGaAs was grown at 465° C. for 8 minutes, followed by an intrinsic GaAs segment growth for two minutes. A Su-8 polymer was spin-coated and etched to the desired height to expose NW tips before the chemical treatment to remove the passivation layer. Finally, silver (Ag) NW contacts were made to the exposed NW tips, which serve as the top contact, and a silver paste bottom contact was fabricated on the bare Si surface.

The optical characteristics of the nanowires were investigated using micro-photoluminescence (μ-PL) at room temperature (RT) and 4K on a low-vibration closed-cycle optical cryostat from Montana Cryo-station using a 633 nm He—Ne laser excitation source. The surface morphology of the NWs was characterized using Carl Zeiss Auriga-BU FIB field emission scanning electron microscopy (SEM). I-V characteristics of ensemble NWs were obtained using two probe Keithley-4200 semiconductor parameter analyzer systems integrated with a radiation shield equipped Lake Shore TTPX probe station. A microHR (LSH-T250) Horiba spectrometer equipped with a tungsten-halogen lamp excitation source was used for studying the spectral photo-response. The optical illumination area was 2×10⁻⁵ m². Finally, a low-frequency noise (LFN) set-up consisting of two independent low-noise current preamplifiers and a dynamic signal analyzer were used to measure the LFN. The measurements were carried out from 1 Hz to 3200 Hz, and the data were averaged over 100 sets of readings. Capacitance-voltage measurement was performed using a Keithley 4215-CVU low-noise capacitance unit capable of measuring frequencies from 10 kHz to 10 MHz. An AC signal of 30 mV and 1 MHz was applied for a typical capacitance measurement of the devices. COMSOL Multiphysics Finite Element Method (FEM) simulations were performed for a range of doping and NW segment thicknesses for the proposed NW structure to estimate the electric-field (E-field) in the heterostructure.

### APD Device Design

A separate absorption of GaAsSb with varying Sb composition, charge sheet layer of p GaAs, and higher bandgap GaAs multiplication region was used in a core-shell configuration. The composition of Sb in the GaAsSb region ranged from 7 to 30 atomic % to tune the absorption wavelengths in the APD structure from 0.95 μm to 1.3 μm, corresponding to a bandgap PL emission range of −0.95 eV to ˜1.25 eV. A doping density and segment thickness were extracted from E-field simulations of the structures of varying segment thickness and doping profiles providing E-field strength ˜1×10⁵ V/cm in the multiplication region to initiate the avalanche mechanism. The doping density of each segment was calculated experimentally using a combination of XPS/UPS, and C-AFM/SKPM. The Be- and Te-doping density of different segments were estimated using a combination of XPS/UPS, from quantifying the corresponding shift in the Fermi level towards the valance and conduction bands, respectively. These values were further confirmed from electron/holes densities computed from I-V characteristics of C-AFM measurements of the single nanowire (SNW). The overall accuracy of the doping density of SNW is estimated to be +/−5%. The individual axial segment growth rates were calculated from SEM images performed on segment-wise core-shell APD structure growth.

A radial thickness of GaAs n-core of ˜35-40 nm was selected based on the targeted growth conditions of n-core on n-Si <111> substrate. Similarly, the choice of doping density of 2.0×10¹⁸/cm3 for the n-GaAs core is representative of the targeted Te-doping conditions to yield improved NW optical properties and verticality. The thicknesses and doping of i-GaAs, p-GaAs, and GaAsSb absorber regions were tuned to minimize the breakdown voltage in the NW device within the potential growth limits. The simulated E-field profile along the radial direction and E field profile of the device at 0 V and 14 V reverse bias, for ˜20 nm radial thickness of the multiplication region was obtained. The simulated value of the E-field was about 5×10⁵ V/cm, sufficient to initiate the avalanche mechanism in GaAs material at a reverse bias≥14 V. Further decrease in the thickness resulted in deviation from APD I-V characteristics; without being bound by theory, this was attributed to an increase in tunneling current.

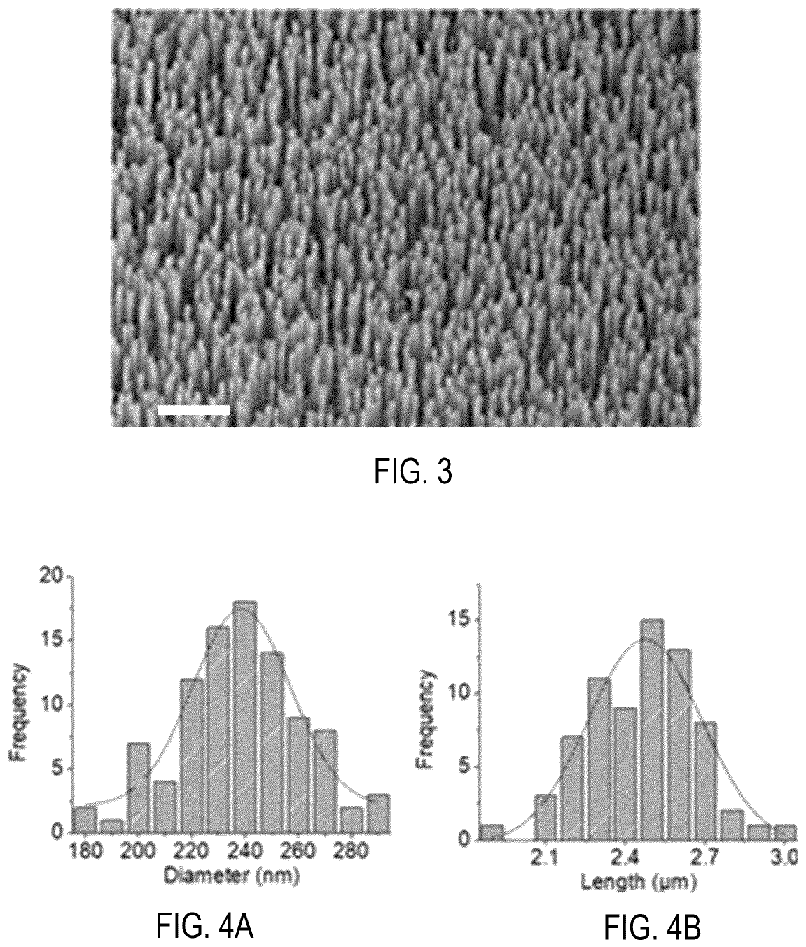

The details of the designed GaAsSb/GaAs CS SACM APD structures are summarized in Table 1 below, and a typical SEM image of as-grown APD NWs is shown in FIG. 3 (scale bar 2 μm). The average length and diameter of NWs were 2.5 μm and 240 nm, respectively. The distribution of NW diameter and length in the samples is shown in FIGS. 4A and 4B, respectively.

TABLE 1
Device structure details.

| Material | Doping (cm⁻³) | Radial Thickness (nm) |
|---|---|---|
| GaAs | 5.0 × 10¹⁸ (n+-type) | 35-40 nm (core) |
| GaAs | Undoped | 20-40 nm (intentionally varied) |
| GaAs | 7.0 × 10¹⁷ (p-type) | 10-15 nm |
| GaAsSb | 7.0 × 10¹⁶ (p-type) | 20-35 nm (intentionally varied) |
| GaAsSb | 7.0 × 10¹⁶ (p-type) | 5-10 nm |
| AlGaAs | Undoped | 10-15 nm |
| GaAs | Undoped | 5-10 nm |

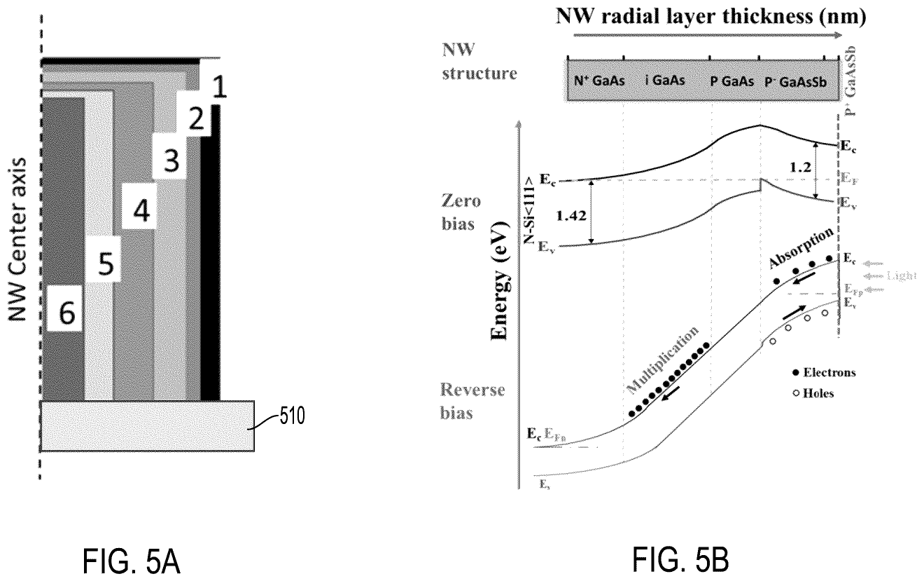

FIGS. 5A and 5B shows a schematic of the core-shell structure and band profile along the radial direction (as of designed SACM-APD NWs at zero bias and reverse bias conditions, respectively. As seen in FIGS. 5A, the SACM-APD 500 comprises AlGaAs/GaAs passivation layer 1, contact P⁺—GaAsSb layer 2, P⁻—GaAsSb absorption layer 3, P—GaAs charge control layer 4, i-GaAs multiplication layer 5, and N⁺-core GaAs layer 6 grown on Si substrate 510.

### Results and Discussions

The characteristics of the samples prepared according to the methods disclosed herein are summarized in Table 2 below.

TABLE 2
A summary of performance metrics for the APD devices

| | | | Multipli- | | |
|---|---|---|---|---|---|
| | Sb | | cation | | Cut-off |
| Sample | incorp | | layer | Maximum | wave- |
| (Description) | (at. %) | V_{BR} | thickness | gain | length |
| R10 | 10% | ~30 V @ | 25-30 nm | >100 at −20 V | 1.1 μm |
| (Reference | | 200K | | and 1060 nm | |
| sample) | | | | (200K) | |
| S10 | 10% | ~35 V @ | 25-30 nm | >250 at −35 V | 1.1 μm |
| (with | | 200K | | and 1060 nm | |
| segment-wise | | | | (200K) | |
| annealing) | | | | | |
| S10T | 10% | — | 25-30 nm | — | — |
| (S10 with | | | | | |
| reduced | | | | | |
| charge | | | | | |
| control layer | | | | | |
| thickness) | | | | | |
| H30 | 30% | ~18 V | 25-30 nm | >150 at 18 V | 1.3 μm |
| (S10T with | | @RT | | and 1060 nm | |
| hybrid device | | | | >50 at 18 V | |
| architecture & | | | | and 1300 nm. | |
| increased Sb | | | | | |
| incorporation) | | | | | |

### Avalanche Characteristics Study: R10

The characteristic features of the first sample SACM-APD device are referred to herein as R10, corresponding to a core n-GaAs core diameter of 35±nm, a radial multiplication thickness of 25-30 nm, a p-GaAs charge control layer of 12±3 nm, and an absorption layer thickness of 25±3 nm with an Sb incorporation of ˜10 at. %.

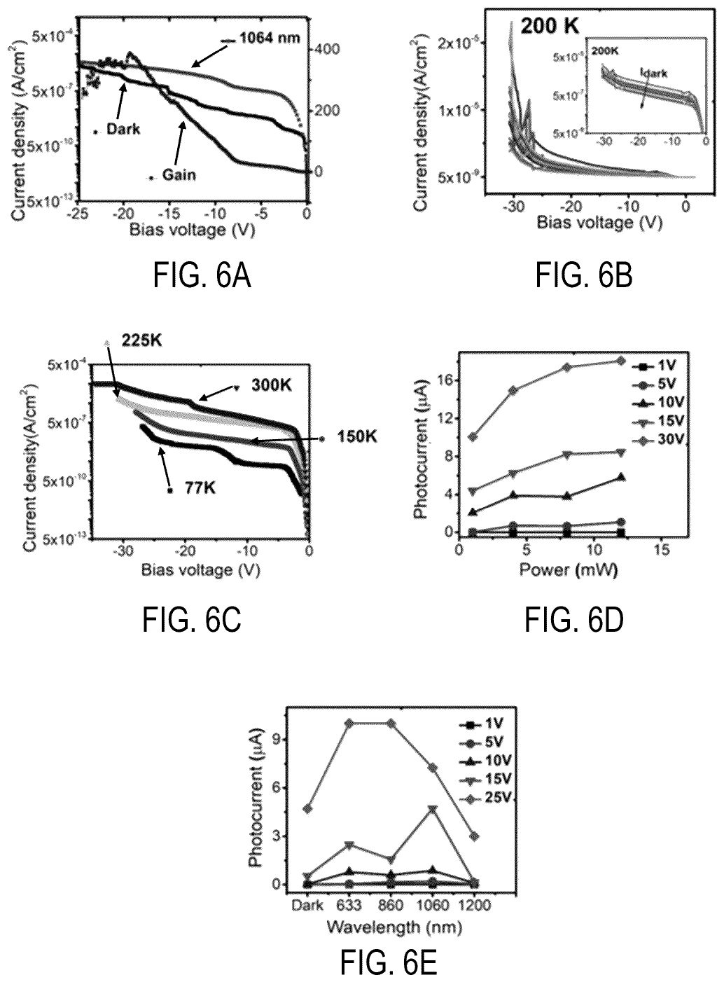

The I-V characteristics of R10 are shown in FIG. 6A under dark and illumination of 1064 nm monochromatic light at 200 K. A low dark current of ˜10 nA was observed at the punch-through voltage of ˜5 V, which gradually increased to ˜10 μA before the onset of breakdown at approximately 30 V at 200 K. The current compliance of the system was set to approximately near the breakdown voltage (VBR), generally to prevent high current flow and any corresponding damage to the device. The dark current at a unity-gain voltage of ˜1.8 V was taken in gain computation, and the dark current value, including the persistent photocurrent increase in the illuminated I-V characteristics, was taken into account in the gain calculation. For a temperature of 200 K, an approximate gain of over 300 was estimated under 1064 nm light illumination with an intensity of ˜8 mW/cm² (FIG. 6A). The gain curve exhibited a small gain up to ˜8 V reverse bias, after which an exponential increase in gain was observed. Consistent with the generation of photocarriers not dominated by impact-ionization, but by photo-absorption up to 8 V reverse bias, beyond which the E-field strength is sufficient to initiate the exponential impact ionization process. A unity-gain responsivity of 0.2-0.25 A/W was achieved at ˜1.8 V. The device showed a marginal increase in dark current after shining light, and without being bound by theory, was attributed to trap filling on illumination and the slow release of carriers by the traps thereafter under dark DC sweep. FIG. 6B shows the result of repeated DC voltage sweeps on VBR at 200 K. A considerable fluctuation in the breakdown is observed during the initial sweeps, with the fluctuation range decreasing and a decrease in dark current on repeated DC I-V sweeps (inset FIG. 6B).

Breakdown characteristics from 150 K to 300 K under dark conditions (FIG. 6C) revealed a positive temperature coefficient, a signature of an avalanche breakdown mechanism. At 200 K, a dark current of ˜10 μA was observed at the breakdown voltage. A temperature coefficient of ˜10 mV/K was observed up to 225 K. A negative dependence on breakdown observed at a temperature exceeding 225 K is consistent with the dominance of the tunneling mechanism over the impact-ionization generation mechanism. A shift of 5-10 V in VBR towards higher voltage was noted after initial sweeps with minimal change on repetition thereafter. The sizeable initial shift in VBR with I-V sweeps is attributed either to annealing of the NW and NW/contact interface and/or burning of very low diameter NWs present under an NW contact, resulting in near-consistent I-V characteristics stabilizing at lower dark current. At 250 K and 77 K, the variation in breakdown characteristics was found to be in the range of 30±3 V and 25±4 V, respectively. Without being bound by theory, this VBR variation is attributed to contributions from (i) the non-uniformity in the thickness of the grown NW samples and/or (ii) doping variation amongst the segments in ensemble NWs. One or both can affect the threshold E-field required for the onset of punch-through and the VBR of the device. Further, the trap filling after the initial sweep factor also contributes to the observed variation in VBR. The power-dependence of photocurrent characteristics (FIG. 6D shows a linear increase in photocurrent with illumination power. For higher bias voltage, an indication of saturation of absorption in nanowires was observed at an illumination power≥7 mW, which may be a result of increased carrier recombination and lateral spreading of the photoexcited carriers due to the presence of traps. Lower variation in breakdown voltage was observed at higher temperatures consistent with the dominance of the generation-current component over the band-to-band tunneling. Wavelength dependence of APD devices (FIG. 6E) at different reverse bias voltages exhibited good photo-absorption up to 1064 nm with the cut-off after 1100 nm. In this example, device failure occurred for the illumination power>15 mW and for reverse bias voltage exceeding 30 V.

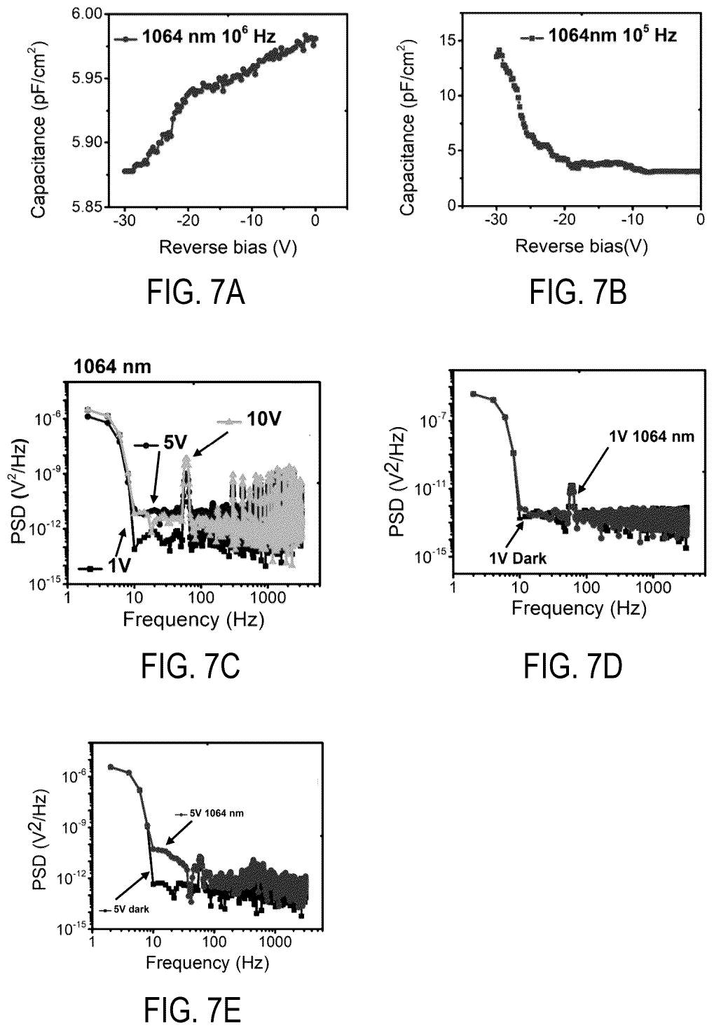

The C—V characteristics at 300 K didn't reveal any clear capacitance variation trend with voltage. At 200 K and under 1064 nm illumination (FIG. 7A) a gradual decrease in capacitance with reverse bias indicates the progressive depletion of the charge layers. At 25 V reverse bias, a rapid change of device capacitance is a signature of rapid channel depletion and increased carrier multiplication. Invariant and stable capacitance for frequencies above 400 kHz is representative of the device capacitance value as the impedance across the capacitance is generally lower at these frequencies. However, at lower frequencies (FIG. 7B shows the C—V at 100 kHz), the ac impedances of resistors and capacitances become comparable, and the C values are not representative of the device capacitance (FIG. 7B).

Low-frequency noise (LFN) characteristics were also examined under dark and illumination settings for a reverse bias up to 10 V (see FIGS. 7C, 7D, and 7E). An increase in average noise level was observed with increasing bias under illumination, especially above the punch-through voltage compared to below punch-through (<5V). A change in noise level is observed only after likely punch-through (see FIGS. 7D and 7E due to increased randomness of the carriers via enhanced generation-recombination (G-R) noise. A signature of 60 Hz noise from the source panel is observed in the LFN characteristics in FIGS. 7C, 7D, and 7E.

### Effect of Segment-Wise Heterostructure Annealing: S10

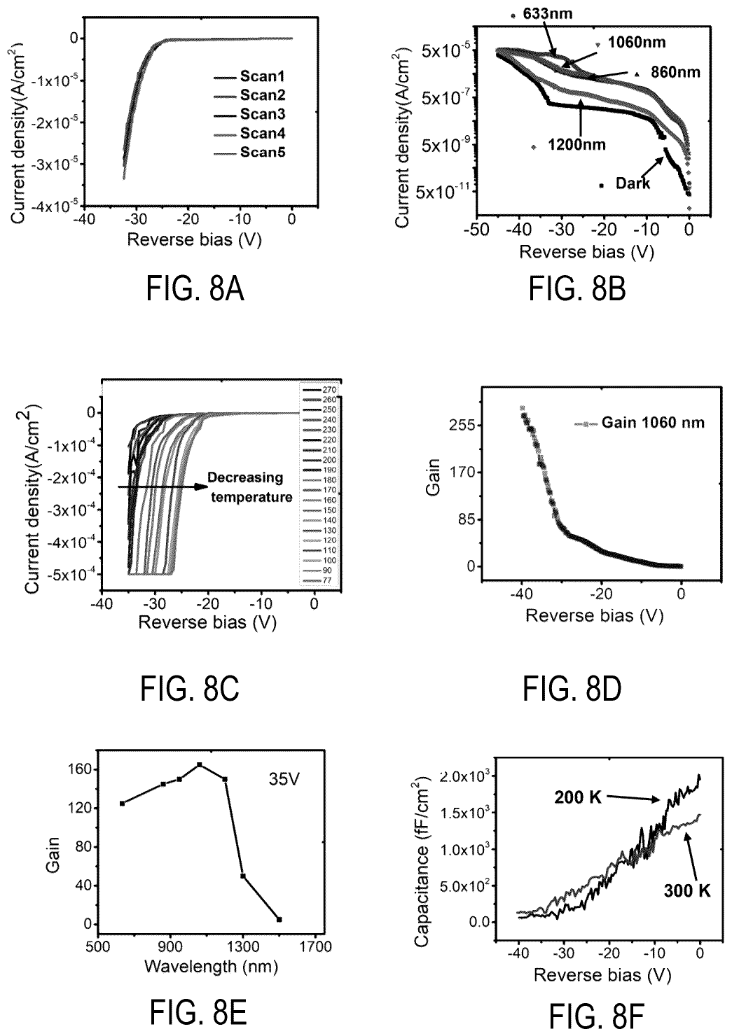

The effects of annealing on the device characteristics were studied under ultra-high vacuum (UHV) @1.5×10-10 Torr ambient for each grown NW segment on the device characteristics. Segment-wise in-situ annealing of the heterostructure NWs for 120 sec was adopted along with post-growth in-situ annealing at 465° C. for 5 minutes. The i-GaAsSb layer segment was compensated with n-type Te-doping for 5 secs over a 1 min interval to achieve lower intrinsic doping in the region. The compensation of the Sb absorber region and increase in absorption efficiency was marked by a substantial increase in the responsivity and external quantum efficiency (EQE). This sample, having ˜10 at. % Sb incorporation in the absorption region combined with segment-wise annealing, shall be referred to as S10 hereafter. The I-V characteristics, gain spectral response, and C—V measurements of the S10 devices were obtained FIGS. 8A-8F.

Increased repeatability of I-V characteristics with a reduction in hysteresis (FIG. 8A) under dark conditions and minimal change in the breakdown characteristics improved compared to the R10 sample, suggesting a trap state reduction in the heterostructure interfaces with segment-wise growth annealing. The device showed spectral sensitivity up to 1100 nm (FIGS. 8B and 8E). A positive temperature coefficient of 30 mV/K of VBR in the reverse bias I-V characteristics observed over a broader temperature range of 77 K-270 K (FIG. 8C) attests to avalanche characteristics. Without being bound by theory, the increase in the temperature coefficient of breakdown voltage from sample R10 to S10 could be caused by dopant redistribution/diffusion in the multiplication segment with annealing. Since the length of the multiplication region is very thin (25-30 nm radially), a small change in the dopant distribution could induce a substantial fluctuation in the device characteristics. A device gain exceeding 150 at 1060 nm wavelength at RT was achieved at reverse bias exceeding 35 V. To confirm avalanche characteristics, C—V measurements were taken at two temperatures of 200 K and 300 K (FIG. 8F), which showed an increase in the device breakdown, suggesting slower depletion of the NW channel with the temperature rise.

### V_{BR} and Absorption Wavelength Tuning: S10T, H30

To further lower the breakdown voltage of the NW APDs, a thinner multiplication layer of GaAs (20-25 nm) was examined to augment the E-field intensity for impact ionization. However, reducing the multiplication thickness below 25-30 nm resulted in a large device dark current beyond punch-through and the disappearance of avalanche breakdown characteristics at room temperature. This sample is referred to as S30T hereafter.

Significant contribution from the axial E-field is very likely in the thin multiplier sample (S30T) and the original sample (R10), as well as the segment-wise annealed sample (S10), as the thicknesses of radial and axial growths are expected to be comparable during vapor-solid (V-S) growth of the shells. Axial growth may be lesser than radial growth, thereby providing a dominant path for carrier multiplication, which becomes more pronounced for smaller multiplication thickness. This is because the E-field through the axial structure can become very high compared to the radial E-field, triggering Zener breakdown. An intentional i-GaAs layer of ˜400 nm was axially grown on top of the n-core GaAs region, intended to suppress the axial E-field strength through the top segment of the NW heterostructure and provide better radial E-field confinement. Compared to the original (R10) and segment-wise annealed (S10) samples, an apparent decrease in axial E-field toward the absorber region is achieved with this design. The new architecture showed a reduction in axial E-field strength, thus lowering the contribution of axial carrier multiplication and/or tunneling in the presence of a high E-field. This design lowered the avalanche breakdown voltage to 18±3 V at RT for the multiplication layer GaAs thickness of ˜20-25 nm. Successful validation of the proposed change in NW APD structure was evident via the change in I-V characteristics and illumination-dependent I-V characteristics.

To extend the spectral sensitivity beyond 1300 nm, the Sb/As flux ratio was increased in the absorption layer. This sample, representing ˜30 at. % Sb incorporation in the absorption region with a thinner multiplication region of 20-nm and segment-wise annealing, shall be referred to as H30 hereafter.

An increase in 2D growths and NW diameter increase of 15±3 nm for the same growth duration is consistent with increased Sb incorporation in the absorption region. Multiple GaAsSb-related peaks from 0.85 eV to 1.05 eV were observed in PL spectra, attributed to the compositional variation in the grown structures in the presence of high Sb flux.

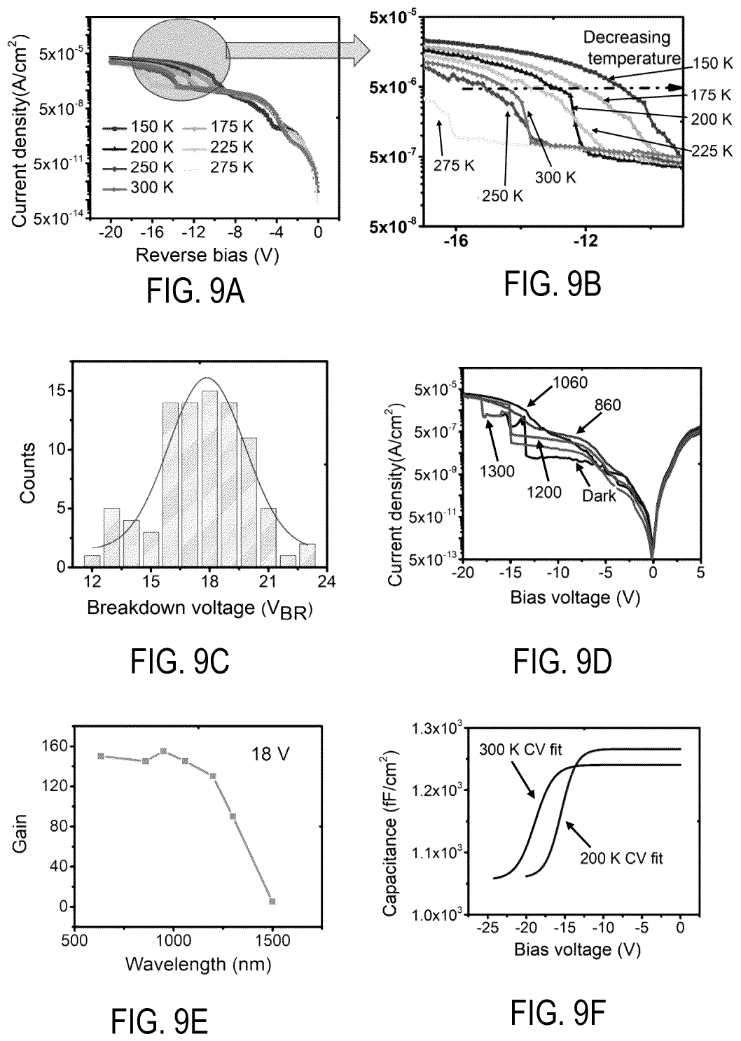

The temperature dependence of the I-V characteristics under dark conditions, ranging from 150 K to 300 K (FIGS. 9A and 9B), showed a positive temperature coefficient of ˜35 mV/K. An increase in temperature coefficient was observed compared to the previous segment-wise annealed sample (S10). Without being bound by theory, this effect is attributed to the possible increase in the dead space effect and radial E-field resulting from multiplication thickness reduction and axial E-field suppression. All of which may change the ionization probability. An increase in dark current magnitude by one order was observed, which is attributed to a much lower bandgap absorption region in this thinner-multiplier region and high Sb composition (H30) sample, resulting in increased band-to-band tunneling through the segment and thus the dark current. FIG. 9B shows the result of numerous dark scans at different spots of the NW sample, with the breakdown voltage fluctuating by ˜3 V from 18 V. Few premature and higher voltage breakdowns are observed at a few spots due to the unavoidable inconsistency of NW diameters and parasitic growth in non-patterned ensemble NW growth. The spectral I-V measurements of the device (FIG. 9C and FIG. 9D) showed gain response up to an illumination wavelength of 1200 nm and tapering off rapidly beyond 1300 nm. C—V characteristics (FIG. 9E) at 1200 nm under illumination carried out at two different temperatures, 300 K and 200 K, exhibited a breakdown at ˜20 V and ˜17 V reverse bias, beyond which the device capacitance remained invariant with further bias increase. The C—V characteristics of the device support the positive temperature coefficient observed in the corresponding I-V plots.

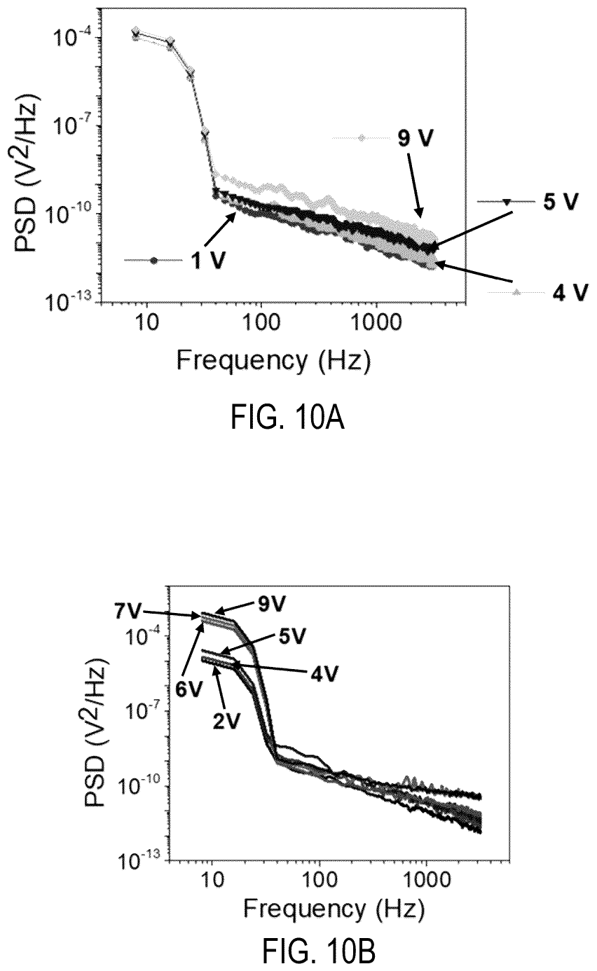

Voltage-dependent LFN measurements of the device under dark are shown in FIGS. 10A and 10B. At 300K, a significant increase in noise was seen with increasing reverse bias, flanked by G-R noise exhibiting Lorentzian characteristics at lower frequencies and a 1/f dependence at higher frequencies, attributed to the presence of traps in the device (FIG. 10A). The 1/f noise at 150 K exhibited less 1/f dependence at bias exceeding 5V, which can be an indication of punch-through voltage. An increase in multiplication noise at a lower temperature (150 K) was markedly indicated by a significant increase in G-R noise and a change in 1/f noise characteristics of the device. The difference in the noise characteristics with temperature is a likely effect of the reduction in the thermal carrier density present in the carrier-multiplication path and trap activation. At lower temperatures, the freeze-out of deeper trap states can also have a role in lowering the E-field to deplete the NW and, thus, decrease the punch-through voltage. This is consistent with the dominance of multiplication noise manifesting as less frequency-dependent noise at bias exceeding ˜5 V (FIG. 10B) in this APD sample. A significant increase in G-R noise at a lower frequency at 6 V reverse bias may be the contribution of the trap activation from a discretized energy level of a certain depth. System limitations impaired noise measurements at bias exceeding 9V.

A room temperature avalanche photodiode with a breakdown voltage of ˜18 V and broad spectral sensing from 633-1300 nm wavelength was achieved with ˜30% Sb incorporation as shown herein.

Following the disclosed methods, including segment-wise annealing of the regions and compensation with a dopant by pulsing with Te for five seconds in one-minute intervals, a core-shell nanowire architecture having additional growth in the tip of the first shell was prepared and is generally described in Table 3.

TABLE 3
A P-I-N Sb30, comprising segment-wise annealed
regions and compensation in Sb region

| | | Radial Thickness |
|---|---|---|
| Material | Doping (cm⁻³) | (nm) |
| GaAs | 5.0 × 10¹⁸ (n+ type) | 35 nm (core) |
| GaAs | undoped | 20 nm |
| GaAs | 7.0 × 10¹⁷ (p type) | 10 nm |
| GaAsSb | 1.0 × 10¹⁶ (p type) | 20 nm |
| (uncompensated) | | |

### Conclusion

This research demonstrates the successful tuning of Sb composition in GaAs/GaAsSb core-shell nanowire SACM-APDs grown on a Si substrate in ensemble configuration, achieving avalanche breakdown and spectral sensing up to 1.3 μm. The study highlights the significant role of annealing in limiting interfacial traps within the core-shell APD architecture, leading to enhanced device performance. The balanced approach, combining heterostructure annealing with a hybrid NW core design, resulted in a remarkably low mean RT breakdown voltage of ˜18 V, accompanied by a positive temperature coefficient of 35 mV/K. This translates to impressive room temperature gain reaching 160 at 1.1 μm and 50 at 1.3 μm at 18 V, with a responsivity of 0.2-0.25 A/W at a punch-through voltage of ˜5V.

The avalanche breakdown mechanism in the NWs was rigorously confirmed through the analysis of temperature-dependent I-V and C—V characteristics. The C—V measurements revealed a maximum capacitance of a few hundred femto-farad under reverse-biased conditions, a crucial aspect for high-speed applications. These findings underscore the viability of the GaAs/GaAsSb material system, leveraging hybrid axial and radial design features, for the fabrication of high-performance nanoscale avalanche photodetector devices. This research paves the way for the development of next-generation optoelectronic devices operating in the near-infrared region with enhanced sensitivity and speed, potentially revolutionizing applications in telecommunications, sensing, and imaging.

### Example 2

### Nanowire Growth

The as-grown ensemble SACM axial NW APDs were grown by self-catalyzed vapor-solid-liquid (VLS) mechanism using molecular beam epitaxy (MBE) on non-patterned n-Si<111> substrates. The NW growth was initiated with a 10 sec Ga flux before opening the Group V fluxes to initiate Ga catalyzed epitaxial NW growth at the pyrometer substrate temperature of 607° C. The Sb₂ and As₄ flux were provided by valved cracker sources operating at 900° C. and 600° C., respectively. Group V/III flux ratio of 10 was used, with an As/Sb ratio of resulting in Sb incorporation of ˜7 at. % in the absorption region. GaTe and Be source materials were used for segmental doping at 540° C. and 925° C., yielding n-type doping ˜10¹⁸/cm³ and p-type doping ˜5×10¹⁷/cm³, respectively. A p+-contact layer with Be cell temperature of 925 C and a group V/III flux ratio of 10 was used for ˜4 at. % Sb incorporation in the segment. NW APD core growth was terminated using As₄ flux to consume the Ga-catalyst droplet present on the NW tip, and the substrate temperature was ramped down to 465° C. for surface passivation. The NW APD core was passivated using vapor-solid (VS) growth of AlGaAs shell for 7 mins followed by a thin GaAs shell˜2 mins to prevent Al oxidation. The individual axial segment growth rates were calculated from SEM images performed on segment-wise axial APD structure growth.

### Nanowire Device Fabrication

SU-8 polymer was spin-coated on as-grown ensemble NW APDs. The excess polymer was etched using reactive ion etching to expose the NW tips before the chemical treatment to remove the AlGaAs passivation layer. Silver (Ag) NWs and silver paste served as top and bottom contacts of the NW APD device, respectively.

### Characterization

The morphological properties of NWs were assessed using the Carl-Zeiss Auriga-BU FIB field emission scanning electron microscope (FESEM).

Micro-photoluminescence (μ-PL) system used for the assessment of the optical properties of NW APDs, comprised of a 633 nm He—Ne laser as the excitation source, 0.32 m double grating monochromator for the wavelength dispersion, and an InGaAs detector with conventional lock-in techniques. A closed-cycle optical cryostat from the Montana cryostat with the sample chamber interfaced with a fiber-coupled confocal microscope captured the 4K PL spectra.

The current-voltage-temperature (I-V-T) characteristics of ensemble NWs were obtained using two probe Keithley-4200 semiconductor parameter analyzer systems integrated with a radiation shield equipped Lake Shore TTPX probe station. A microHR (LSH-T250) Horiba spectrometer equipped with a tungsten-halogen lamp excitation source was used with an optical illumination area of 2.25×10⁻⁴ m² for studying the device photoresponse. The I-V characteristics of the NW APD device were measured by limiting the current compliance of the measurement system to 10⁻⁴ A; the NW APD devices were found to degrade during the operation at higher current conduction.

The capacitance-voltage (C—V) measurement was performed using a Keithley source meter with the incremental change in the voltage by 30 mV. Keysight 35670 dynamic signal analyzer equipped with two independent low noise current preamplifiers was used for low-frequency noise measurements. The source-drain bias was provided by the internal batteries of these two amplifiers, and its output terminals were connected to two different channels of the dynamic signal analyzer. Measurements were carried out from 10 Hz to 3200 Hz, and the data were averaged over 500 sets of readings.

### Nanowire Simulation

The E-field simulation for the single SACM axial GaAsSb/GaAs heterostructure NW APD was performed using the Semiconductor Module of COMSOL Multiphysics at 300 K.

### SACM Axial NW APD Schematic and Electric Field Simulation

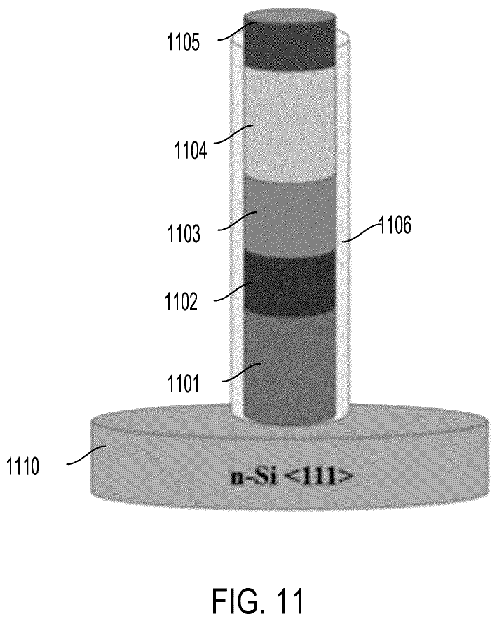

FIG. 11 illustrates the schematic of single SACM axial GaAsSb/GaAs heterostructure NW APD passivated with lattice-matched AlGaAs layer to mitigate the Fermi level pinning effect caused by surface states. It should be understood that the components of the single SACM axial GaAsSb/GaAs heterostructure may comprise the same, similar, or substantially similar components, features, dimensions, chemical composition as NW structures in FIG. 1 and FIG. 2. The average axial dimension of the single NW structure may be ˜110±5 nm (measured over 50 NWs) based on the SEM measurements of the optimized initial n-GaAs NW core segment growth on the n-Si<111> substrate. The choice of the SACM structure exploited the NIR absorption tuning of GaAsSb material with Sb composition and reduce band-to-band tunneling in the higher bandgap GaAs multiplication region. The i-GaAsSb absorption region segment is separated from the i-GaAs avalanche multiplication region to suppress the carrier tunneling component. The SACM Axial NW grown on Si type substrate 1110 comprises n-i-p heterojunction comprising n-type GaAs core 1101, intrinsic GaAs core segment 1102, p⁻-type GaAs core segment 1103, an intrinsic type GaAsSb core segment 1104, a P type GaAsSb core segment 1105, and passivation layer 1106 comprising Al, Ga, As, or a combination thereof (for example, AlGaAs/GaAs) enclosing the n-i-p core. In some embodiments, single SACM axial GaAsSb/GaAs heterostructure of FIG. 11 may comprise additional layers, i.e., first, second, third, and/or fourth shell as described above with respect to FIG. 1 and FIG. 2 enclosing the core segment. In some embodiment these additional layers may be enclosed by passivation layer 1106.

In some embodiments, Sb content of each region described in FIG. 11 may independently comprise about 2 at. % to about 12 at. %, about 2 at. %, about 3 at. %, about 4 at. %, about 5 at. %, about 6 at. %, about 7 at. %, about 8 at. %, about 9 at. %, about 10 at. %, about 11 at. %, or about 12 at. %. of Sb. In some embodiments, Sb content of p-GaAs region of the GaAsSb NW-based core-shell n-i-p heterojunction photodetector may be lower than Sb content of the i-GaAsSb region.

COMSOL Multiphysics software was used to study the E-field variation in the NW structure for different segment thicknesses. For simulation purposes, all the surfaces were treated as non-ideal. From simulation analysis the multiplication region thickness and charge control region doping variations were identified as two parameters affecting the modulating E-field distribution throughout the NW APD structure. Reduction in the multiplication region thickness led to E-field intensity enhancement for a given charge control layer doping. Increasing the charge control layer doping resulted in a further increase in graded E-field distribution across the NW device but at the expense of higher operating avalanche breakdown voltage (V_{BR}). Without being bound by theory, increased doping in the charge control layer is promoted tunneling current from the absorption region at a higher reverse bias leading to a large dark current. A doping value of ˜5×10¹⁷/cm³ in the charge control layer and multiplication region thickness of ˜200 nm was selected to target low V_{BR}˜−10 V. In addition, a smaller multiplication region favored deterministic gain characteristics, perhaps due to increased dominance of dead space effect. The E-field contour plot generated at −10 V exhibiting high E-field>5×10⁵ V/cm (for avalanche breakdown in GaAs system) in the multiplication region based on the schematic of the single SACM axial NW APD simulation results showing that carriers attain saturation velocity before entering the multiplication region with a marginal graded E-field distribution in the charge control region, enhancing probabilistic impact ionization.

### Nanowire Growth Optimization

Careful attention to different axial NW growth-related issues yielded a successful the avalanche mechanism in the NW structure, as disclosed herein.

The growth of charge control p-doped GaAs NW segment with efficient Be-incorporation and minimum inter-segmental dopant diffusion was one important factor. Deactivation of Be-dopant occurs in GaAs NWs grown under an As-rich environment due to the formation of stable surface AsGa (As antisite) defects, which are responsible for Fermi level pinning at the NW surface, causing an electron accumulation layer. This was suppressed by reducing As₄/Ga flux ratio to half those used in the other n and i-segment growths. Further Be-dopant diffusion from charge control GaAs layer to multiplication layer can lead to domination by the tunneling mechanism (Zener breakdown) and result in internal gain variation in axial NW configuration. To reduce Be-dopant diffusion from the charge control segment in the underneath i-GaAs multiplication segment, Be shutters were opened and closed for a few seconds for the first few cycles of the p-GaAs growth.

The growth of GaAsSb material system of the uniform diameter as that of underlying GaAs structure was deemed another relevant feature, requiring judicious selection of growth parameters. Sb is a well-known surfactant, aiding lateral overgrowth and inverse tapering of the NWs (which can lead to early growth termination and undesirable shell growth). These can create a potential shunt path for carriers generated in the absorption region due to thin radial shell growth. An increase in substrate temperature by 3° C. at the start of GaAsSb segment growth suppressed the radial shell growth, minimizing the shunt current path. The substrate temperature was subsequently lowered by 5° C. during the growth for enhanced Sb incorporation.

As the top p+ GaAsSb contact layer determines the light absorption characteristics of the axial APD device, a higher bandgap layer consisting of lower Sb composition with a targeted thickness of ˜300 nm was used.

### SEM and Photoluminescence (PL)

The free-standing ensemble SACM axial GaAsSb/GaAs NW APDs growth under disclosed conditions yielded high-density vertical NWs on n-Si <111> substrate. The self-catalyzed growth with the passivating shell exhibited an average NW length of ˜1.8±0.12 μm and an average diameter of ˜110±5 nm (measured over 50 NWs). The disclosed method produced uniform NW APD diameter.

The 4K-PL spectra measurement revealed two prominent peaks at 1.28 eV and 1.48 eV, corresponding to the compositions of GaAsSb in the absorption and GaAs segments, respectively. A broad FWHM˜0.34 eV of GaAsSb spectra and a lack of sharp low energy onset is consistent with the presence of defects, generally attributed to acceptor vacancies in the intrinsic-Sb material system.

### Current-Voltage (I-V) Measurements

Multiple RT I-V sweeps under dark were performed on the ensemble SACM axial NW APD device samples. Under reverse bias operation, a low dark current from 10 μA to 100 μA was observed before the onset of breakdown at −10±2.5 V, where the current increased sharply by 3 to 4 orders of magnitude, a signature of avalanche breakdown. Repeated I-V sweeps shifted the V_{BR} from −10 V to −7.5 V, which became stable. The range of V_{BR} obtained was consistent with those computed based on the E-field simulation of this structure.

Under 1.064 μm illumination, the I-V characteristics of the NW APDs displayed low photocurrent at zero bias, indicative of incomplete depletion of the absorption region. With increased reverse bias, a surge in photocurrent was observed at ˜−2 V, which plateaued at −3 V. This is a typical signature of punch-through voltage or unity gain point corresponding to the depletion region extending to the absorption region edge. Therefore, −3 V was considered the unity gain (UG) point providing an estimate that avoided overestimating the gain in the NW APDs of the present application. On illumination, the V_{BR} shifted to a lower bias of ˜−6 V and remained invariant in the subsequent scans under both dark and light. This shift towards lower V_{BR} during the initial sweeps under both dark and illumination may be: (a) annihilation or redistribution of traps during the repeated sweep and illumination reaching a steady state of trap density thereafter and/or (b) the formation of a secondary electric field within the NW device due to pinning of the Fermi level at depletion region edge (formed in absorption region) at the polymer (SU-8 in this case) surface where NW tips are exposed. Both can contribute the E-field necessary for pre-mature avalanche breakdown at a comparatively lower reverse bias than expected from the simulation results.

Gain (M) was calculated using McIntyre's equation: Gain (M)=(Iᵢₗₗ−I_{dark})/((Iᵢₗₗ−I_{dark}) UG revealed a monotonous increase from ˜20 just below V_{BR} (FIG. 2-4(b)) to ˜700 after V_{BR} for the as-grown ensemble APDs.

The presence of the avalanche mechanism in these devices was further corroborated by the temperature-dependent I-V measurements under dark. A positive V_{BR} coefficient˜+12.6 mV/K in the temperature range of 77 K to 300 K showed distinct sharp breakdown characteristics under dark, consistent with a band-to-band avalanche mechanism. The low value of the temperature-dependent V_{BR} coefficient suggests the dominance of the dead space effect in these NW APDs and is attributed to the thin multiplication region thickness of 200 nm in the NW APDs. Testing the device at a higher temperature (350 K) yielded a significant rise in current due to increased background thermal carrier generation and carrier tunneling, terminating the avalanche process in the NW APDs. Current saturation observed at both the extremum of reverse and forward bias voltages is due to testing instrument compliance as described above.

A broad spectral response was observed for the ensemble SACM axial NW APDs, covering visible to the near-infrared region with a cut-off around 1.2 μm. The maximum response of ˜1.064 μm is consistent with the PL peak energy corresponding to the GaAsSb absorption segment. The power-dependent excitation study at a low reverse bias of −1 V displays an S-curve behavior, characteristic of trap filling. The invariant behavior of photocurrent with excitation power at a higher reverse bias of −6 V and −8 V further confirms the avalanche breakdown mechanism under illumination at −6 V.

### C—V Measurements:

The RT 1 MHz C—V characteristics of the ensemble SACM axial NW APDs under 1.064 μm illumination exhibited a low capacitance of ˜1 pF up to −3 V followed by a monotonic decrease with increasing reverse bias up to −6 V. Under illumination, capacitance is independent of reverse bias increasing from −1 V to −3 V, attributed to the depletion width expansion being offset by the optical generation of charge carriers. With a further rise in reverse bias, the capacitance value declined rapidly and saturated at ˜0.67 pF beyond −6 V, signifying complete depletion of NW APD structure corresponding to avalanche breakdown voltage.

A C—V measurement study was performed at a range of frequencies, to ascertain the presence of any interface trap states, which influence the ability of the carriers to follow the AC signal. At 1 MHz, a low capacitance of ˜0.3 pF is consistent with the small footprint of the NWs and is representative of the geometrical capacitance associated with the absorption and the multiplication regions. The negative capacitance observed at lower frequencies likely originates from the accumulation of charge carriers at the interface and/or charging/discharging of the traps arising from the impact loss process, where excess energy gained by electrons in the high E-field knock-off electrons trapped in the states below the Fermi level. At lower frequencies, the impedance associated with the capacitance becomes so large that the values are not representative of the true capacitance value. However, the trend in the onset of the negative capacitance occurring at a lower bias region with lower frequency is indicative of the probing of larger trap cross section. Under illumination, the negative capacitance was not as pronounced at lower voltages, suggesting the traps were being filled by the photocarriers.

### Noise Measurements

Low-frequency noise spectroscopy (LFN) of NW APD at RT under illumination exhibited a noise power spectral density (PSD) roll-off after 10 Hz till 40 Hz for a reverse bias variation from −1 V to −6 V. All the PSD curves follow a Lorentzian fit at a lower frequency, suggesting the dominance of generation-recombination noise due to the presence of traps, which are consistent with the broad 4K-PL spectral line shape for GaAsSb related peak and C—V measurements. Beyond the corner frequency of 40 Hz, frequency-independent white noise was observed. A sharp rise in the noise floor by ˜2 orders of magnitude at −3 V and again at −6 V correlates well with the additional noise contribution at punch through voltage caused by the maximum generation of carriers in the absorption region and carrier multiplication at the onset of avalanche mechanism, respectively.

The temperature-dependence of noise under dark at 77 K for an applied bias of −5 V revealed suppression of generation-recombination noise at low frequency with overall noise floor increased compared to RT. Without being bound by theory, the suppression in generation-recombination noise at 77 K is assigned to the freezing of trapped charge carriers. However, the elevated noise floor at this temperature is due to the dominance of the avalanche mechanism at a lower voltage of ˜-5 V compared to RT, consistent with the temperature-dependent I-V characteristics. The noise characteristics show a 1/f dependence revealing a significant contribution of traps in the avalanche process even at 77 K. Thus, the temperature-dependent LFN noise spectroscopy validated the avalanche mechanism in the PD.

The responsivity of these NWs at 1.064 μm was 0.17-0.38 A/W at the punch-through voltage of ˜−3 V. Addressing the small volume of the absorption region, non-transparent NW contact, lack of antireflection layer on top, and non-uniform nature of ensemble NW growth, which can impact adversely the light trapping features, can improve NW responsivity.

### Conclusion

Shown herein is the successful RT operation of ensemble GaAsSb/GaAs based SACM axial NW APDs grown on non-patterned Si substrates at 1.064 μm wavelength. Detailed E-field simulations and careful attention to growth techniques with optical and electrical characterizations were used to achieve the disclosed axial NW SACM APDs. An increase in multiplication gains was observed from ˜20 below V_{BR} to ˜700 above V_{BR}. Positive temperature dependence of breakdown voltage˜+12.6 mV/K further confirmed avalanche breakdown as the gain mechanism in the SACM NW APDs manufactured here. C—V and temperature-dependent noise characteristics also validated the punch-through voltage values and the presence of avalanche gain mechanism in the NW APDs, determined from the I-V characteristics. The ensemble SACM NW APD device demonstrated a broad spectral RT response with cut-off wavelength˜1.2 μm with responsivity˜0.17-0.38 A/W at −3 V. The C—V and LFN analysis indicated the presence of traps, and the V_{BR} shifts were correlated to the trap variation. Improving the contact/NW interface, in-situ segmental annealing may improve the quality of grown material segments; different surface passivation layers may additionally subdue the surface trap effects leading to improved ensemble NW APD device performance.

### Example 3

As shown herein, a C-S n-i-p junction GaAsSb NWs was grown by self-assisted molecular beam epitaxy (MBE) with variation in intrinsic, ‘i’-region width and a simple Te compensation approach to improve the device performance, as undoped GaAsSb is slightly p-type, attributed to residual acceptor impurity, namely Ga vacancy-related defects and Ga antisite defects (VGaGasb). To reduce the background carrier concentration, n-dopant pulsing in the form of GaTe source was introduced during the growth of the i-GaAsSb shell. The disclosed methods demonstrate fabrication and characterization of MBE-grown room temperature (RT) conventional devices for the application of near-IR photodetectors at wavelengths up to at least about 1.1 μm with high rectification ratio, enhanced responsivity, detectivity, and low series resistance. The intrinsic region thickness along with Te compensation are found to be an important factor to enhance responsivity and detectivity.

The hybrid axial C-S n-i-p GaAsSb NW structure was designed with a core-n-i axial structure as opposed to the conventional n-core structure, which is surrounded by the intrinsic shell of different Sb % composition to boost the absorption volume of the intrinsic region without compromising the series resistance and to extend the device's operational wavelength to 1.5 μm. This structure minimizes the impact of over-etching of p- and i-segments encountered in the conventional C-S NW structure that may lead to the formation of core n-GaAsSb Schottky diode, which is detrimental to the ensemble NW IRPD device. Based on the design disclosed herein, a high quality and high device performance resulted in responsivity of 18 A/W and detectivity of 1.1×10¹³ Jones in the NIR wavelength region up to 1.5 μm. These are ensemble NWs on non-patterned substrates, but following the methods disclosed herein, ensemble heterostructure NW on patterned substrates can be prepared.

### Growth and Characterization

Three MBE grown C-S n-i-p GaAsSb NW PD samples are disclosed: two NW sample structures follow conventional C-S n-i-p configuration as seen in FIG. 1, with intrinsic segment growth times of 25 mins and 30 mins and Sb of ˜5 at. %, referred to as I-25 and I-30 samples, respectively. To improve the C-S n-i-p GaAsSb NW, the i-segment was varied from 15 to 40 mins growth duration. The third sample, referred to as MI, is the hybrid axial C-S configuration of the n-i-p structure (as seen in FIG. 2), with intrinsic growth time of 35 mins and Sb % of ˜26 at. %.

Self-catalyzed n-i-p GaAs₁₋ₓSbₓ NWs were grown on heavily doped n-type Si (111) substrate at a constant group-III beam equivalent pressure (BEP) of 6×10⁻⁷ Torr. GaTe cell temperature of 540° C., and Be cell temperature of 925° C. were used to achieve the carrier concentration of ˜10¹⁹ cm⁻³ using MBE EPI 930 system. In all growths, the Ga shutter was opened for 9 secs before the opening of As flux and GaTe to grow the Te-doped GaAs stem with As₄ beam equivalent pressure (BEP) of 6×10⁻⁶ Torr at 615° C. The substrate temperature was further reduced to 590° C. for the growth of Te-doped GaAs₁₋ₓSbₓ with an As/Sb ratio of 9, achieving Sb incorporation of ˜3 at %, resulting in the formation of a uniform diameter of ˜70 nm. The Ga droplet on top of the NW was consumed by simultaneously shutting off Ga, Sb, and Te shutters. To be consistent with segment thickness, the growth rate was calculated by growing each segment independently for different durations, and the respective segment thickness in the p-i-n heterostructure was then determined from these radial growth rates and the growth duration. The i-GaAs₁₋ₓSbₓ shell was grown around the n-GaAsSb core at 550° C. with the intermittent opening of Te for 2 sec during intrinsic shell growth (Te compensation), achieving a thickness of ˜40 nm and ˜48 nm and lowering As/Sb flux for Sb incorporations of ˜5 at % in the intrinsic region for two different sets of samples. The growth of Be-doped GaAs₁₋ₓSbₓ of 40 nm thickness was initiated by opening Be flux and reducing the As/Sb ratio to 9, followed by in-situ annealing for 5 mins. Finally, the passivation shell of AlGaAs/GaAs was grown for 3 mins/2 mins respectively, followed by 5 mins of vacuum annealing.

In the case of the MI sample, the following changes were implemented. (1) The oxidation time was increased, with a goal of reducing parasitic growth and noise. (2) Two short segments of GaAs followed by Te-doped GaAs were carried out with a goal of reducing the shunt current. (3) Core Te-doped GaAs wavelength cutoff at ˜1.1 μm with a significantly higher responsivity (about 120 A/W @-3 V bias) and detectivity (about 1.1×10¹³ Jones) at room temperature. Frequency and bias-independent capacitance in the pico-Farad Sbₓ with an As/Sb ratio of 9 and Sb concentration of 3 at % was grown at 590° C. The i-GaAs₁₋ₓSbₓ of length 800 nm, with the same Sb concentration as the Te-doped segment, was subsequently grown with Te opening intermittently for a few seconds to improve absorption volume. The temperature was decreased to 465° C. for the droplet consumption. Shell growth of i-GaAs₁₋ₓSbₓ with Sb of ˜26 at. % was initiated at 550° C., followed by in-situ annealing for 5 mins, during which the growth is paused for an abrupt uniform junction. The length and the diameter were found to be 2.1±0.1 μm and 230±12 nm (I-25 sample), 2.1±0.1 μm and 246±12 nm (I-30 sample), and 2.2±0.1 μm and 242±12 nm, (MI sample) respectively.

Carl Zeiss Auriga-BU FIB field emission scanning electron microscope (FESEM) was used to determine the morphology of the NWs. The μ-PL measurements were conducted at 4K and RT to determine the optical characteristics of the NWs as is known in the art. For ensemble PD, NWs samples were spin-coated with an insulating and transparent SU-8 photoresist, which served as a protective layer and filler for NWs. NW core tip from SU-8 was exposed using reactive ion etching (RIE). Metal contacts for the NW device consisted of silver NWs and silver paste serving as top and bottom contacts, respectively. I-V performance of ensemble NWs was assessed for various wavelengths ranging from 633 nm to 1500 nm at room and low temperature using Keithley 4200 characterization system by the two-probe method. The schematics of ensemble NW and SNW I-V measurements. Low-frequency noise (LFN) measurement was conducted to determine the noise characteristic of NWs. Capacitance-voltage (C—V) characteristics were performed from the frequency range of 1 kHz-1 MHz in reverse bias voltage between 0 and −3V, using a Hewlett Packard LCR meter. Conductive-atomic force microscopy (C-AFM) was used to characterize the photoresponse of a single nanowire (SNW). During the current imaging scan, a DC bias was applied between the Ti/Ir conductive tips with a spring constant of 2 N/m and tip radius of 25 nm and the sample substrate, in which the cantilever was grounded. Laser of wavelength 860 nm, and power of 1 mW, were used to illuminate the NW.

### Results and Discussion

As shown herein variation in the intrinsic region width enabled a high-performance conventional C-S n-i-p GaAsSb NW IRPD with an emission wavelength of up to 1.1 μm. Bandgap engineering of a novel hybrid axial C-S n-i-p GaAsSb PD with higher Sb % (GaAs_{0.74}Sb_{0.26}) redshifted the device operational wavelength up to 1.5 μm.

### Photoluminescence

The core-shell n-i-p GaAsSb ensemble NWs and SNW of I-25 and I-30 samples were prepared according to a method of the present disclosure. A comparison of RT and 4K PL of the I-25 sample revealed a 66-fold increase in intensity and reduction in full width at half maxima (FWHM) at 4K PL. These PL spectra can be deconvoluted into three peaks. For example, RT PL spectra of I-sample exhibit peaks at ˜1.16 eV (FWHM of 101 meV), ˜1.22 eV (FWHM of 150 meV), and ˜1.23 eV (FWHM of 70 meV), which correspond to emission from intrinsic (peak 1), n-core (peak 2) and p-shell (peak 3) respectively. At 4K, these are blue-shifted to ˜1.24 eV (FWHM of 62 meV), ˜1.29 eV (FWHM of 83 meV), and ˜1.30 eV (FWHM of 72 meV), respectively. In the case of the I-30 sample, a marginal variation in intensity compared to the I-25 sample was observed. The RT PL measurement of I-30 sample exhibit peaks at ˜1.16 eV (FWHM of 90 meV), ˜1.18 eV (FWHM of 100 meV), and ˜1.22 eV (FWHM of 128 meV), and 4K PL emission indicated a further blueshift to ˜1.25 eV (FWHM of 76 meV), ˜1.29 eV (FWHM of 44 meV) and ˜1.34 eV (FWHM of 68 meV), respectively. The lower energy PL spectral peak (1.25 eV) was attributed to the emission from the intrinsic region GaAsSb, while the higher energy peaks were attributed to the n- and p-GaAsSb segments. The blue shift of the PL positions of the I-30 sample relative to I-25 may be associated with the change in the type of transition from type II to type I or a combination of both the types.

### I-V and LFN Measurements of Ensemble PD.

The I-V characteristics of the I-25 and I-30 IRPD devices under dark and illumination in the spectral wavelength region of 633 nm to 1300 nm show a dark current of 6 nA and 5 nA with photogenerated current at −1 V in the range of 6 μA and 600 μA, respectively. Sample I-30 shows the highest on-off ratio of 1.2×10⁵ for the wavelength of 1100 nm at −1V, evident from the increase in photoresponse of the respective I-V plot. The series resistance was calculated from the slope of the I-V curve above the turn-on voltage and shunt resistance was calculated from the slope of the I-V curve near the origin. The shunt resistance likely arises from the interface of metallic silver NW contact and core of the NW tips, and the leakage current at the bottom through the shell may be due to the presence of some 2D growth in the ensemble NWs. The rectification ratio, series resistance, and shunt resistance of I-25 were 2, 8×10⁶ ohms, and 5×10⁹ ohms, while for I-30, these were 111, 7×10⁵ ohms, and 5×10⁹ ohms, respectively. An increased rectification ratio accompanied by lower series resistance of the I-30 sample relative to the I-25 sample is consistent with the improved junction quality of the I-30 NW sample, which attributed to the better quality of the thicker intrinsic layer.

Additionally, the I-25 and I-30 samples exhibited responsivity of 1.8 A/W and 190 A/W at −1V for the longer cut-off wavelength of 1100 nm and started decreasing from 1200 nm. The external quantum efficiency (EQE) was 2.2×10³% and 2.2×10⁴% for the I-25 and I-30 samples, respectively. The increase in responsivity and the enhanced EQE correlates with the importance of increased absorption intrinsic region on device performance. Between the two samples, I-displayed a high detectivity over a broad spectral range from 800 to 1,100 nm at −1 V and −2V and was found to be 1.1×10¹⁴ Jones at 1100 nm illumination wavelength. LFN spectra of these two samples revealed noise PSD roll off after 4 Hz with comparatively lower PSD observed in the I-30 sample. Lorentzian fit identified a major contributor to be the generation-recombination noise. Beyond 10 Hz, I-25 was dominated by 1/f flicker noise with the slope of one, while sample I-30 exhibited only frequency-independent white noise. The enhanced responsivity, EQE, detectivity of the IRPD, and the absence of flicker noise observed in the I-30 sample suggested that increased absorption volume and better quality of the intrinsic layer with shell thickness played a role in improving the device metrics.

C-S n-i-p GaAsSb NIRPD at the Wavelength of 1.5 μm.

The hybrid axial C-S n-i-p NW structure had an extended operating wavelength to 1.5 μm by increasing Sb concentration and tailoring the junction to retain the quantum efficiency and photoresponse of the earlier described samples.

The hybrid design containing both axial and radial intrinsic regions as disclosed herein enables high-performance PD beyond 1.5 μm. The axial C-S n-i-p NW structure can be expanded to other advanced architectures.

### Conclusion

The conventional n-i-p configuration prepared according to the methods of the present application produced a high device performance n-i-p GaAsSb C-S configured NWs with responsivity and detectivity of 190 A/W and 1.1×10¹⁴ Jones, respectively, up to 1.1 μm illumination wavelength by tailoring the intrinsic region shell thickness grown on top of the core-Te-doped GaAsSb and surrounded by shell Be-doped GaAsSb. A novel hybrid axial C-S n-i-p GaAsSb NW design structure prepared according to the methods of the present application enabled enhanced light absorption volume and extension of the wavelength region of operation to 1.5 μm with responsivity and detectivity of 18 A/W and 1.1×10¹³ Jones, respectively. Increasing Sb composition or diluting the amount of N incorporation in the intrinsic region can extend the operating wavelength detection beyond 1.5 μm, using the methods and NW structures disclosed herein. The patterned growth of C-S NWs further reduces parasitic growth and enables better PD performance. The p-i-n and n-i-p junction designs disclosed herein can be used to realize high-performance PD beyond 1.5 μm, making the products broadly applicable to a variety of optoelectronic device applications.

### Example 4

P-i-n GaAsSb NWs were grown on p-Si (111) substrate in a solid source MBE EPI 930 system. Ga catalyzed growth was initiated at a substrate temperature of 618° C. with the opening of the Ga shutter for 13 secs before opening As shutter for GaAs stem growth. After the stem growth, the substrate temperature was decreased to 590° C. for the p-i-n GaAsSb nanowire growth, often referred to as a two-step growth approach. At the growth temperature of 590° C., the NW growth was initiated by growing a p-segment of ˜280±10 nm in length, followed by variable i-segment thickness. The p-i-n NW core growth was terminated after growing an n-segment of 200±10 nm length. Each segment was grown independently to rule out the possibility of inconsistency in segment thickness measurements and axial growth rate. Based on the axial growth rate of each segment, the overall segment growth duration was determined. In the growth of GaAsSb p-i-n NWs, gallium telluride (GaTe) captive source at the source temperature of 520° C. was used to achieve a carrier concentration of ˜5×10¹⁸ cm⁻³ and beryllium (Be) was used as a p-dopant at the source temperature of 920° C. to achieve a dopant concentration of 5×10¹⁷ cm⁻³. During the i-segment growth, the intrinsic p-type nature of i-GaAsSb NWs was compensated by the intermittent supply of Te using a GaTe captive source. The As/Sb flux ratio of 4 and 6 corresponding to Sb compositions of about 9 at % and about 4 at. % were used for the i- and doped segments, respectively. NW core growth was terminated by consuming the Ga droplets under the As-rich condition. The substrate temperature was lowered to 465° C. for the passivation shell growth of AlGaAs, followed by growth of the skin shell of GaAs to prevent possible oxidation of Al. All NWs in this Example had this AlGaAs/GaAs combination as passivating shell layers. Ga and the As flux corresponded to yield a nominal planar GaAs growth of 0.5 ML/s.

### Characterization

NW morphology was assessed using the Carl-Zeiss Auriga field emission scanning electron microscope (FESEM). The μ-photoluminescence (μ-PL) measurement used a 633 nm He—Ne laser as the excitation source, with a 0.32 m double grating monochromator for wavelength dispersion, liquid nitrogen cooled InGaAs detector, and conventional lock-in amplifier techniques for PL emission detection. A closed-cycle optical cryostat from Montana Cryostation, with the sample chamber interfaced with a fiber-coupled confocal microscope, was used to determine the 4K PL characteristics.

The ensemble photodetector device was fabricated by spin-coating the NW ensemble prepared herein with SU-8 as the filling layer and subsequent deep reactive ion etching (DRIE) to expose the NW tips for top contact fabrication. Silver NWs served as the top contact and the silver paste was used as the contact on Si. The electrical properties of the ensemble PD device were assessed using the two-probe technique. The response of the PD to optical illumination was determined using the Keithley-4200 source meter and the microHR (LSH-T250) spectrometer of Horiba with the tungsten-halogen lamp as the excitation source. The capacitance-voltage (C—V) measurement was performed using the Keithley source meter with the incremental change (30 mV) in the AC voltage. Low-frequency noise spectroscopy setup was based on a cross-correlation technique, consisting of two independent low noise current preamplifiers connected to the device. Its outputs were connected to two different channels of the digital signal analyzer (DSA). The frequency-dependent noise measurement was taken at a reverse bias of 1 V, and the data represent an average of 100 spectral runs.

### Result and Discussion

The NW growth conditions generally dictates the performance of heterostructure axial p-i-n NWs. Amongst multiple growth challenges, three variables having an impact on the NW device performance are (i) intrinsic p-nature of GaAsSb, (ii) droplet reservoir and self-radial growth, and (iii) strain effects in heterostructures. The following approaches were adopted to mitigate these challenges and yield successful GaAsSb heterostructure NW devices.

### NWs Growth Optimization: Compensation of Intrinsic GaAsSb Segment

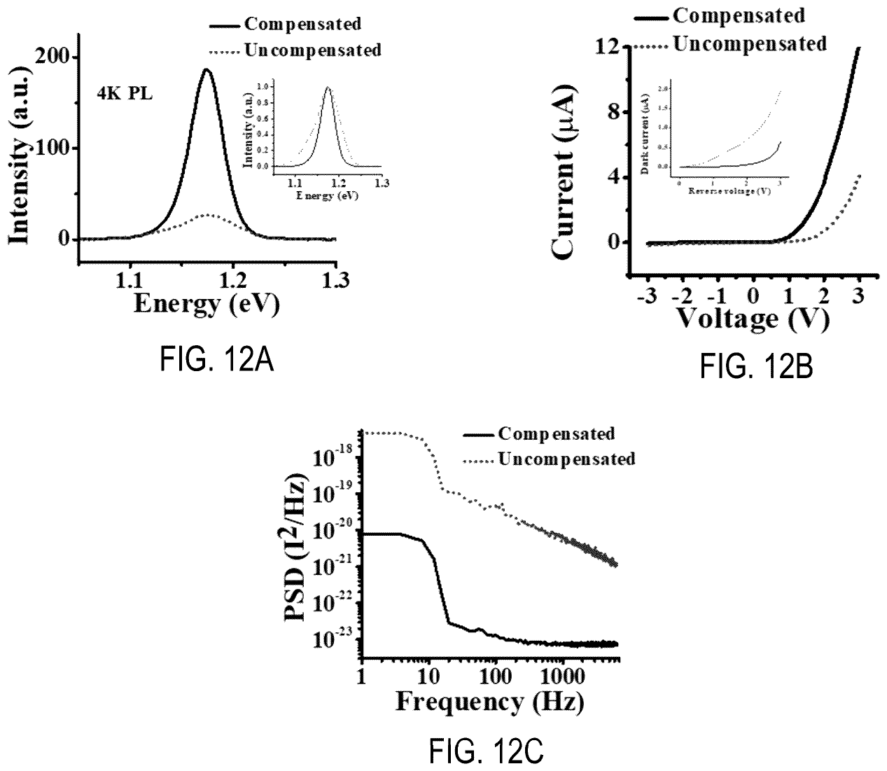

One of the first challenges is the growth of i-GaAsSb with lower residual carrier concentration due to the intrinsic p-type nature of GaAsSb, as these can cause potential fluctuations within the NW crystal lattice, requiring a much higher bias voltage to reach complete depletion in a p-i-n device. Further, the diffusion current from the undepleted region can contribute to the overall thermal equilibrium current inducing the leaky behavior, while the absence of electric field (E-field) promotes the photocarrier recombination. All these characteristics adversely impact the dark and photocurrent of the junction and the device noise, degrading the device performance. Compensation of i-segment with n-dopant Te mitigated this effect. The optical and electrical properties of the compensated and uncompensated i-segments were compared to assess the impact of compensation. The 4K PL emission intensity of the compensated i-segment exhibited ˜8-fold enhancements (FIG. 12A) accompanied by the reduction in FWHM (inset in FIG. 12A) from 0.068 eV to 0.04 eV as compared to the uncompensated segment. The broader PL linewidth in the uncompensated core is consistent with emission from the intrinsic defects convoluted with the band-to-band emission suppressing the overall emission intensity. The effectiveness of Te compensation of the intrinsic defects in compensated NWs is evidenced by enhanced PL emission intensity with narrower linewidth and early onset of the band-to-band emission (FIG. 12A).

The compensation effect was also assessed using electrical characteristics of corresponding p-i-n configured NW. The thicknesses of p-, i-, and n-segments were 280 nm, 700 nm, and 200 nm, respectively. Uncompensated i-segment exhibited bias-dependent dark current under reverse bias, while Te compensation revealed the voltage-independent I-V spectra till 2 V (FIG. 12B). The ideality factor value calculated utilizing the forward bias after the turn-on voltage in the uncompensated core reduced from 5.4 to 2.5 for compensated NWs. These observations suggest the presence of high intrinsic defect density in the uncompensated NWs, which act as charge carrier generation centers, contributing to the enhanced reverse saturation current with bias-dependent characteristics. These manifest in a high ideality factor value in the forward bias due to increased tunneling. Generally, a higher dark current is expected to enhance the noise level in the optoelectronic devices due to the increased potential fluctuations, so the LFN spectra of the two core NWs were examined. LFN spectroscopy of both the compensated and the uncompensated cores revealed the G-R noise as the dominant noise source at low frequency transitioning to 1/f flicker or frequency-independent white noise, respectively at a corner frequency of ˜20 Hz (FIG. 12C). Further, the G-R noise at low frequency is suppressed by two orders of magnitude in the compensated samples. The lower dark current associated with white noise and suppressed G-R noise is consistent with defect compensation in the i-layer, reduced potential fluctuations, and correspond to improved material quality. The magnitude of background carrier concentration in the i-segment can be calculated using the one-sided junction approximation employing equation 1, involving the C—V measurement.

$$\frac{1}{{C}^{2}} = \frac{2 ( {V}_{bi} + {V}_{R} )}{q ε {N}_{i}} \qquad Eq . 1$$

where, V_{bi} is the built-in potential, V_{R} is the applied reverse bias voltage, q is the electronic charge, ε is the permittivity of the semiconductor NWs and Nᵢ is the background carrier concentration in the i-segment of the axial p-i-n NWs.

The best linear fit of the experimental data to equation 1 yielded a carrier concentration of ˜6×10¹⁵ cm⁻³ and ˜3.2×10¹⁵ cm⁻³ in the uncompensated and the compensated i-segments, respectively. The value of the carrier concentration variation in both the compensated and uncompensated NW core was studied in 34 samples. The improved PL emission with reduced linewidth, accompanied by the voltage-independent dark current and frequency independent noise, attests to the Te compensation's efficacy on the NW optical and electrical properties. In addition, reduced noise level and background doping level in the compensated NW sample demonstrates the intermittent supply of Te during the i-segment growth as shown herein was an effective compensation for the p-nature of the i-GaAsSb segment.

Optimization of the Respective Segment Thickness of Axial p-i-n NWs

The photoabsorption and efficient collection of the photogenerated carriers in the active i-region generally dictate the performance of p-i-n NWs in the axial configuration, which is strongly influenced by the segment lengths, emphasizing the importance of stringent segment thickness. The top n-segment consisted of a higher bandgap GaAsSb composition corresponding to Sb composition of 4 at. %, serving as a window to the incoming photons exclusively absorbed in the i-region. A minimum segment thickness of 200 nm was necessary to dope the n-region adequately and efficiently deplete the active region. The segment is long enough to alleviate any complexity arising from contact formation requiring the top segment to be partially etched to expose the tip. Similarly, the higher bandgap p-GaAsSb (Sb composition of 4 at. %) segment thickness of ˜280 nm at the bottom was found to be adequate to minimize the substrate effects.

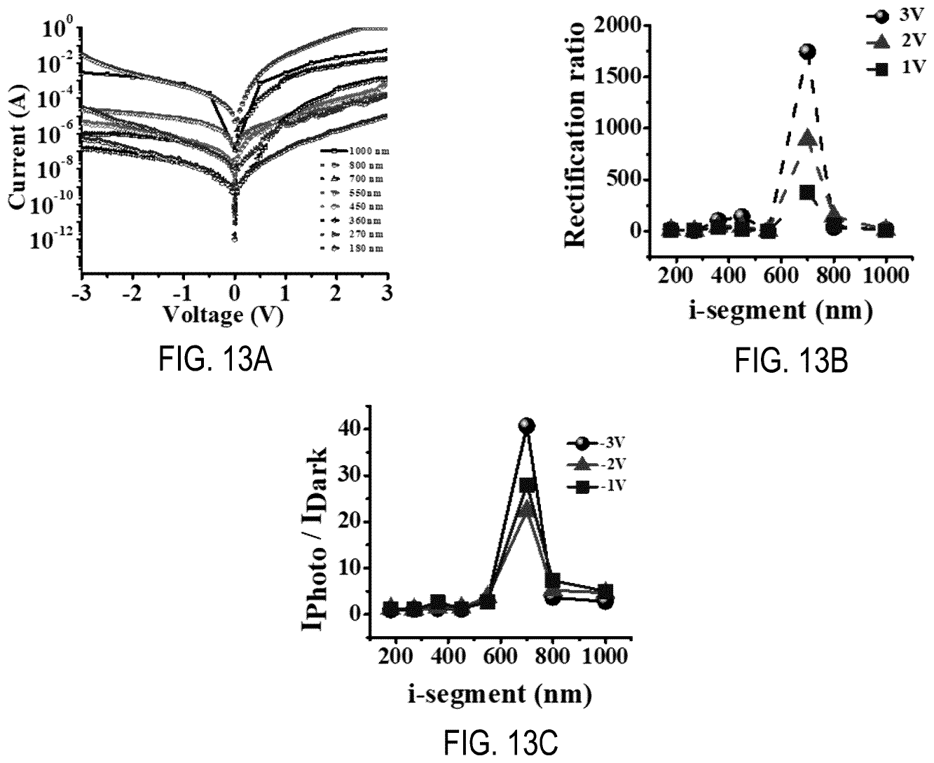

Control of i-segment thickness correlates to achieving the high-performance axial p-i-n NWs. The effects of i-segment length (ranging from 1 μm to 180 nm) on room temperature (RT) electrical properties were investigated. The thicker i-segment NW samples (beyond 800 nm) demonstrated significantly higher dark current, while segment thickness of 550 nm and lower exhibited voltage-dependent dark current characteristics under reverse bias. Further, I-V characteristics (FIG. 13A) showed the best rectifying characteristics for i-thickness of 700 nm and transitioned to more symmetric behavior on either end of the thickness region examined. Similarly, photosensitivity defined as photocurrent to the dark current ratio

$$( \frac{{I}_{P}}{{I}_{D}} )$$

is also the highest at 700 nm i-thickness (FIG. 13C). Based on the corresponding C—V characteristics, the unintentional doping Ni of the i-segment was estimated to be ˜3.2×10¹⁵ cm⁻³. The depletion region, W, was calculated to be 720 nm using the standard Equation 2 for the p-i-n junction in the reverse bias. This value is in good agreement with the observed optimized i-thickness.

$$W = {( \frac{2 ε ( {V}_{bi} + {V}_{R} )}{{qN}_{i}} )}^{0.5} \qquad Eq . 2$$

Without being bound by theory, the observed deterioration of the dark I-V characteristics at higher thickness was attributed to an undepleted region contributing to higher dark current and symmetric I-V characteristics. For smaller thicknesses, the voltage-dependent reverse bias current indicated the onset of the tunnel-induced current conduction mechanism leading again to more symmetric I-V features with a low rectification ratio. Lower active region volume at lower thickness and recombination of photocarriers in the undepleted portion of the i-segment at higher thickness are other factors that contribute to lowering the photosensitivity. The NW electrical performance was severely degraded for both the longer and shorter i-segments and the 700 nm i-segment thickness was used in the following studies.

### Approach to Minimize the Reservoir Effect and the Radial Overgrowth

Heterostructure axial p-i-n NWs growth suffers from the infamous reservoir effect having a deleterious impact on the optical and electrical properties. To suppress the reservoir effect of Be after p-segment growth, three different approaches were employed, viz. terminating the Be supply in the last 1 minute of the p-segment growth (Sample A), reducing the substrate temperature by 5° C. during the growth interruption of 1 minute to increase the droplet supersaturation to facilitate Be precipitation (Sample B), and pulsing the Be source for the last 30 sec of the p-segment growth at an interval of 5 sec (Sample C). The second approach (Sample B) effectively suppressed the reservoir effect, as evidenced by the improved electrical and optical properties accompanied by the lower background carrier concentration in the i-segment.

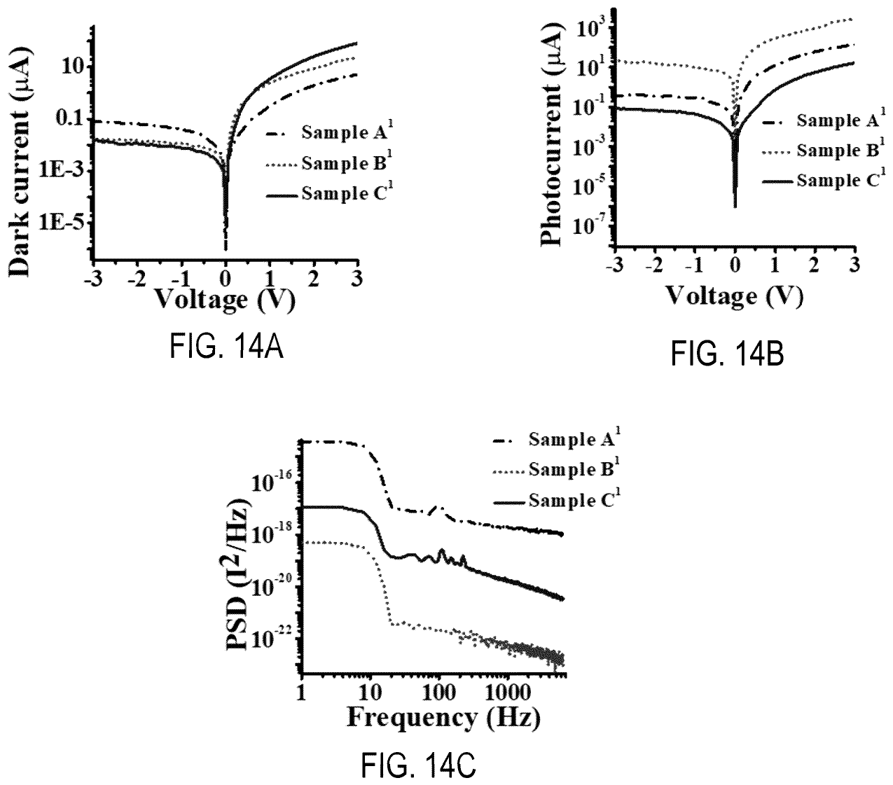

Radial overgrowth is another challenge in axial p-i-n NW growth, as it introduces the shunt path for parasitic conduction. To suppress the radial overgrowth, three different approaches were examined: (1) Increasing the consecutive segment growth temperature due to the VS radial overgrowth being favored at lower growth temperatures (Sample A¹), (2) high-temperature annealing after each segment growth (Sample B¹), and (3) increased As/Sb flux ratio for the consecutive segment growths (Sample C¹). Growth temperatures were 590° C., 595° C., and 600° C. for the respective p-, i-, and n-segments, (Sample A¹); high-temperature in-situ segment annealing was carried out at 5° C. above the growth temperature (Sample B¹); and the As/Sb flux ratio was marginally increased from 9 in p-segment to 10 in i-segment to 11 in n-segment (Sample C¹). The dark current variation in the NW samples adopting these three approaches (FIG. 14A) showed a significantly higher rectification ratio, improved photosensitivity (FIG. 14B), and suppressed noise level (FIG. 14C) in all the three samples, indicative of successful suppression of radial overgrowth. As the shell overgrowth measurement from SEM cannot be deterministic, the changes in radial overgrowth of a few nanometers were inferred from the variation in the shunt resistance. Amongst the three samples, Sample B¹ demonstrated improved electrical properties, suggesting that the radial overgrowth was suppressed in Sample B¹. This conclusion was also borne out by the shunt resistances (R_{Sh}) values computed by fitting the experimental dark I-V characteristics with a linear equation close to ˜0 V bias. The inverse of the slope of linear fitting yielded shunt resistances of 10 MΩ (Sample A¹), 125 MΩ (Sample B¹), and 5 MΩ (Sample C¹). Significant enhancement of the shunt resistances in these samples compared to 0.2 MΩ in the regular sample described above, further supports the success of these three approaches in minimizing the radial overgrowth in the NW samples, with Sample B¹ exhibiting the highest shunt resistance consistent with the best electrical characteristics.

### Growth Interruption

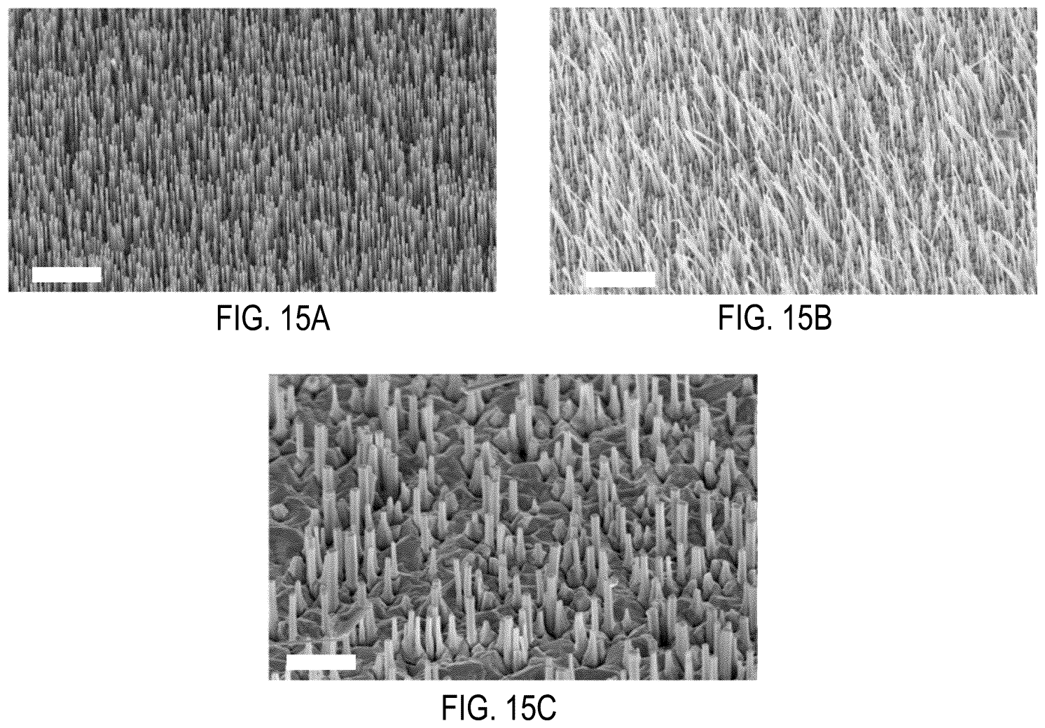

During the growth of p-i-n GaAsSb NWs in the axial configuration, growth interruption between different segments was importance to achieving high-quality vertical NWs (FIG. 15A, scale bar 2 μm), while NWs without growth interruption exhibited gradual bending of the NWs during the growth (FIG. 15B, scale bar 2 μm), possibly due to stress accumulation at the interface. The growth interruption of a minute disclosed herein may provide time for interface reconstruction reducing the density of dangling bonds and minimizing the interface stress. Interruption for a more extended period, i.e., 2 mins (FIG. 15C, scale bar 1 μm), resulted in the unstable seed droplet trimming the NWs. Thus, growth interruption of 1 min before the subsequent segment growth was a successful approach to achieving high density vertical axial p-i-n NWs. Alternately, an interruption of less than 2 minutes or less than 1 minute may be appropriate in certain preparations and the best duration can be identified by one of skill in the art for the specific elemental combinations.

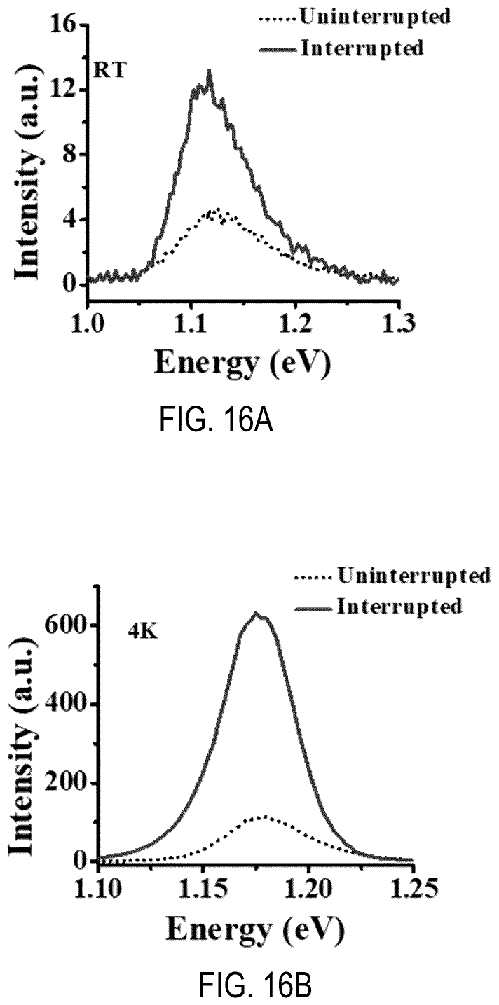

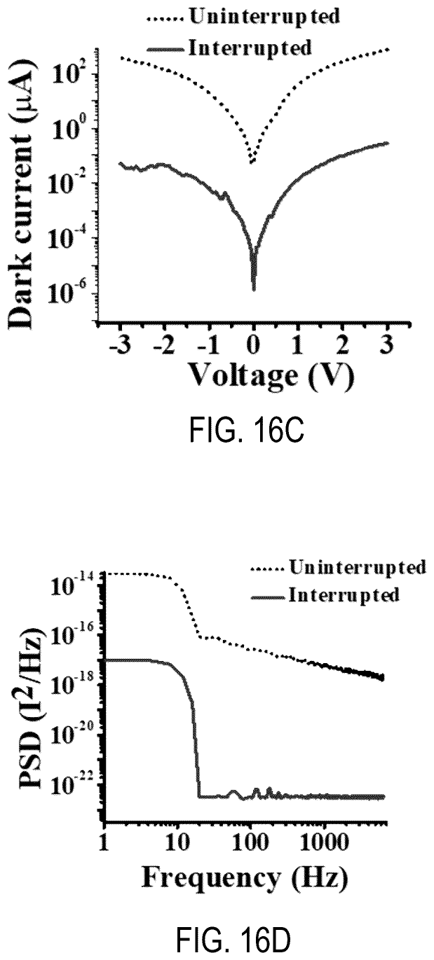

The efficacy of growth interruption after each segment growth was demonstrated by significant improvement in the RT and 4K PL intensity (FIGS. 16A and 16B), suppression in the dark current, and noise by several orders of magnitude (FIGS. 16C and 16D).

GaAsSb p-i-n Ensemble NWs and Corresponding PDs

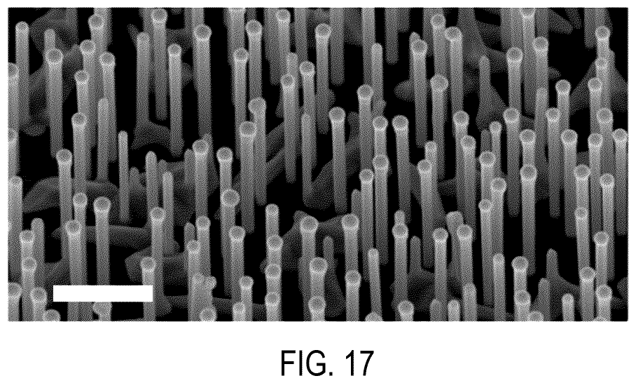

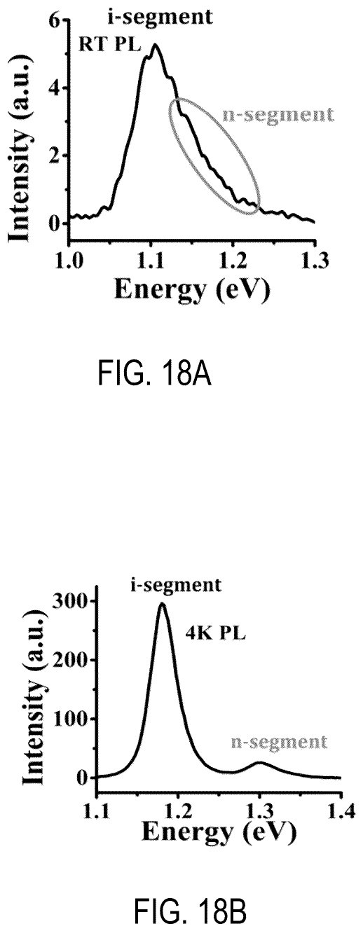

GaAsSb p-i-n ensemble NWs of an average length of ˜1.5±0.1 μm and a diameter of ˜148±8 nm were grown under the optimized growth conditions in the axial configuration as seen in FIG. 17. The existence of the catalyst droplet at the NW tip suggests that the VLS growth ceases only during the passivation shell growth. RT PL signal of the NW ensemble itself (FIG. 18A) suggests the successful realization of high-quality heterostructure NWs. The RT PL exhibits asymmetrical spectra with a single peak at ˜1.2 eV and a long exponential decay tail on the higher energy side. Without being bound by theory, the long tail may be due to the overlap of the n- and i-segment peaks, as 4K PL (FIG. 18C) revealed two distinct peaks at ˜1.2 eV and ˜1.3 eV, respectively. Excitation dependence at 4K of 1.2 eV PL peak indicated band-to-band transition.

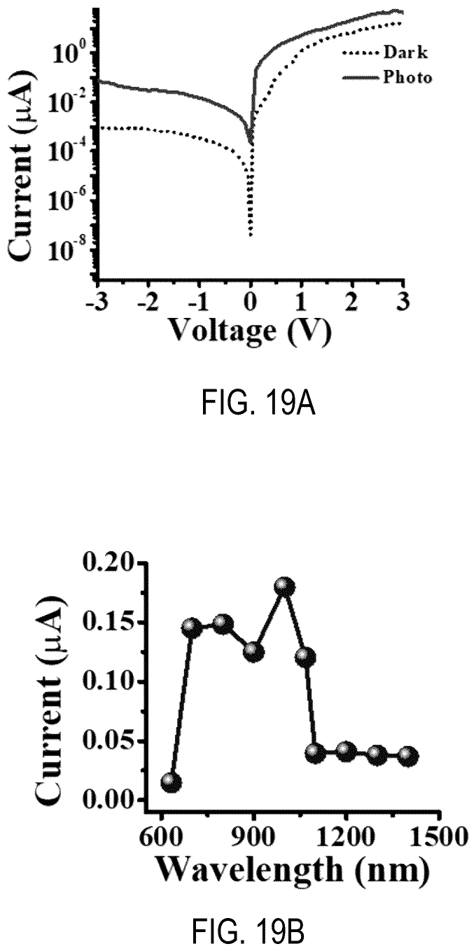

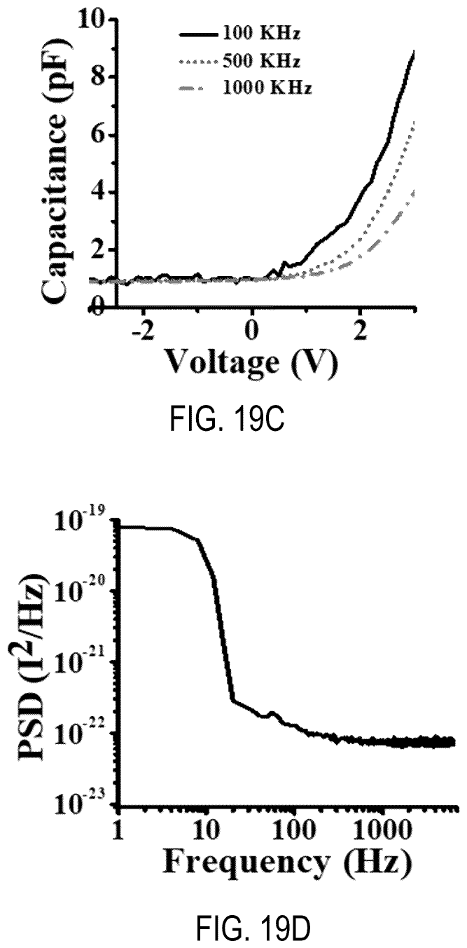

The ensemble NW PD fabricated using the heterostructure p-i-n NWs demonstrated rectifying dark I-V characteristics (FIG. 19A) with the photocurrent enhanced by 3 orders of magnitude.

The spectral response measured at −3V (FIG. 19B) displays the bandpass characteristics with the lower and high cutoff wavelengths at ˜0.6 μm and ˜1.1 μm, respectively. The lower cutoff wavelength is generally influenced by thermalization loss, enhanced surface absorption, and screening of photogenerated carriers, while the higher wavelength cutoff corresponds to the material bandgap, consistent with the RT PL peak wavelength.

The C—V plot at different frequencies (FIG. 19C) revealed invariant capacitance in the reverse bias for all frequencies, indicating complete depletion of the neutral region and high-quality i-segment with reduced defect density. Capacitance increase in forward bias is a typical signature of diffusion capacitance due to effective diffusion of the charge carriers from the neutral to depletion region. The inability to follow the ac signal at a higher frequency led to the observed frequency dependence. Low values of capacitance in the pF range are indicative of the prospects of the heterostructure NW for high-speed applications. The LFN spectra (FIG. 19D) exhibit G-R noise as a dominant noise source with a corner frequency of ˜20 Hz transitioning to a weak 1/f noise. The responsivity and detectivity of the PDs are 120 A/W and 1.3×10¹³ Jones, respectively.

The randomness of the NW growth can significantly influence the PD performance. The successful performance of the NW of the present example grown on unpatterned substrates can be improved by growth of axial p-i-n NWs on patterned substrates.

### Conclusion

As shown herein, it is possible to overcome several delimiting factors for the successful realization of p-i-n axial configured GaAsSb ensemble NWs PD on a non-patterned p-type Si substrate. Te-compensation of intrinsic GaAsSb was shown to compensate for material defects and decrease the intrinsic p-type carrier concentration of this material system, leading to lower dark device currents. Reduction in the substrate temperature during growth interruption between different segments resulted in improved optical and electrical properties of the grown NWs. High-temperature in-situ individual segment annealing suppressed the radial overgrowth, leading to a higher rectification ratio, improved photosensitivity, and the suppressed noise level in the p-i-n NW device. The p-i-n ensemble NWs were used in the successful fabrication of heterojunction GaAsSb axial p-i-n NW ensemble photodetector with a responsivity of ˜120 A/W, a detectivity of ˜1.1×10¹³ Jones at −3V reverse bias, with cut-off wavelength at 1.1 μm. As is familiar to those of skill in the art and consistent with the disclosure herein, improved responsivity and detectivity as well as cut-off wavelength can result from growth of the nanowires of the present application on a patterned substrate.

### Example 5

Samples were fabricated on n-type Si (111) substrates using the vapor-liquid-solid (VLS) mechanism by molecular beam epitaxy (MBE). The process utilized As₄ and Sb₂ species with growth temperatures ranging from 550 to 615° C. The gallium (Ga) cell and arsenic (As) cracker cell temperatures were set to achieve a beam equivalent pressure (BEP) ratio of V/III=15 with a Ga flux of 2×10⁻⁷ Torr. A 14-second Ga pre-deposition was employed to initiate self-catalyzed growth. The n/i-GaAs core was then developed at 610° C. with a BEP ratio of 15, followed by the growth of intrinsic and Be-doped GaAs shell segments at 550° C. with a BEP ratio of 16. Subsequently, the GaAsSb absorption layer and a highly p-doped GaAsSb contact layer was grown at same substrate temperature of 550° C., with the Sb composition varying between approximately 5 to 30 atomic percent. Finally, an AlGaAs passivation layer was deposited at 465° C. for 8 minutes, followed by the growth of an intrinsic GaAs segment for 3 minutes. A SU-8 polymer was spin-coated and subsequently etched to the desired height to expose the nanowire (NW) tips before undergoing a chemical treatment to remove the passivation layer. Silver (Ag) NW contacts were applied to the exposed NW tips, and silver paste was used on the bare Si surface to establish top and bottom contacts, respectively, linking an ensemble of NWs in parallel.

### Low Breakdown Voltage

To reduce the breakdown voltage and enhance the gain, a comprehensive analysis focusing on the dimensions, including the thickness of the multiplication and charge layers, is essential. To achieve finer control over radial growth, the Ga flux has been reduced to 2×10⁻⁷ Torr. This reduction in Ga flux for self-catalyzed growth not only yields superior crystal but also facilitates precise control over composition and ensures uniform coverage of the shell. Such a strategy results in smoother NW surfaces and more consistent diameters, which are critical for producing a high-quality material with few defects. Additionally, this method improves material utilization, reduces waste, and simplifies the fabrication process through improved uniformity. The impact of multiplication thickness, along with a combination of charge layer thickness and doping concentration within the charge region on avalanche breakdown in SACM structures was investigated using both COMSOL simulations and experimental I-V method, particularly focusing on GaAs material.

It will be understood that various details of the presently disclosed subject matter may be changed without departing from the scope of the presently disclosed subject matter. Furthermore, the foregoing description is for the purpose of illustration only, and not for the purpose of limitation.

Any and all compositions, uses, and/or methods shown and/or described expressly or by implication in the information provided herewith, including but not limited to features that may be apparent and/or understood by those of skill in the art.

What is claimed is:

1. An avalanche photodiode comprising:
at least one GaAs/GaAsSb core-shell nanowire grown on a silicon substrate,
wherein the GaAs/GaAsSb core-shell nanowire comprises:
a nanowire core comprising an n-type GaAs; and
a first shell enclosing the core;
a second shell enclosing the first shell
wherein the first shell comprises an intrinsic type GaAs and is a multiplication region of the avalanche photodiode,
wherein the second shell comprises a p-type GaAs and is a charge control region of the avalanche photodiode, and
wherein the photodiode operates in a near-infrared region.

2. The avalanche photodiode of claim 1, further comprising a third shell enclosing the second shell, wherein the third shell comprises a p⁻-type GaAsSb and is an absorption region of the avalanche photodiode.

3. The avalanche photodiode of claim 2, further comprising a fourth shell enclosing the third shell, wherein the fourth shell comprises a p⁺-type GaAsSb and is a contact region of the avalanche photodiode.

4. The avalanche photodiode of claim 1, further comprising a passivation layer enclosing the shell, wherein the passivation layer comprises Al, Ga, As, or a combination thereof.

5. The avalanche photodiode of claim 1, wherein diameter of the nanowire core is from about 30 nm to about 50 nm.

6. The avalanche photodiode of claim 1, wherein radial thickness of the first shell is from about 30 nm to about 40 nm.

7. The avalanche photodiode of claim 1, wherein radial thickness of the second shell is from about 10 nm to about 20 nm.

8. The avalanche photodiode of claim 2, wherein radial thickness of the third shell is from about 20 nm to about 30 nm.

9. The avalanche photodiode of claim 3, wherein radial thickness of the fourth shell from about 20 nm to about 30 nm.

10. The avalanche photodiode of claim 3, wherein the first shell, the second shell, the third shell, and the fourth shell independently comprise from about 6 at. % to about 12 at. % of Sb.

11. The avalanche photodiode of claim 3, wherein the third shell and the fourth shell independently comprise a band gap from about 0.95 eV to about 1.25 eV.

12. An avalanche photodiode comprising:
at least one GaAs/GaAsSb axial nanowire grown on a silicon substrate comprising:
a nanowire core comprising a bottom n-type GaAs stem region, a middle intrinsic-GaAs region, and an upper p-GaAs region; and
a passivation layer enclosing the nanowire core comprising Al, Ga, As, or a combination thereof.

13. The avalanche photodiode of claim 12, wherein the nanowire core further comprises an intrinsic-GaAsSb region on top of the p-GaAs region, and a p-GaAsSb region on top of the intrinsic-GaAsSb region.

14. The avalanche photodiode of claim 12, wherein the intrinsic-GaAsSb region comprises an Sb content from about 6 at. % to about 10 at. % Sb.

15. The avalanche photodiode of claim 12, wherein the p-GaAsSb region comprises an Sb content from about 2 at. % to about 6 at. % Sb, wherein the Sb content of the p-GaAsSb region is lower than an Sb content of the intrinsic —GaAsSb region.

16. An avalanche photodiode comprising:
at least one hybrid axial/core-shell nanowire grown on a silicon substrate,
wherein the hybrid axial/core-shell nanowire core-shell nanowire comprises:
a nanowire core comprising a bottom n-type GaAsSb stem region, a middle intrinsic-GaAsSb region, and an upper p-GaAsSb region; and
a shell enclosing the nanowire core comprising intrinsic-GaAsSb, wherein the shell is optionally doped with a Te-dopant.

17. The avalanche photodiode of claim 16, wherein the shell enclosing the nanowire core is a first shell, and the hybrid axial/core-shell nanowire further comprises a second shell enclosing the first shell, wherein the second shell comprises p-GaAsSb and is optionally doped with a Be-dopant.

18. The avalanche photodiode of claim 16, wherein the middle intrinsic-GaAsSb region and the shell independently comprise an Sb content from about 2 at. % to about 12 at. %.

19. The avalanche photodiode of claim 16, further comprising a passivation layer enclosing the shell, wherein the passivation layer comprises Al, Ga, As, or a combination thereof.

20. The avalanche photodiode of claim 16, wherein the shell comprises i-GaAs_{0.74}Sb_{0.26}.
